(19) United States
(12) Patent Application Publication
(10) Pub. No.: US 2026/0150359 A1
(43) Pub. Date: May 28, 2026

(54) SILICON CARBIDE SEMICONDUCTOR WAFER, SILICON CARBIDE SEMICONDUCTOR DEVICE, AND METHOD FOR MANUFACTURING SILICON CARBIDE SINGLE CRYSTAL

(71) Applicant: DENSO CORPORATION, Kariya-city (JP)

(72) Inventors: Makoto OCHI, Kariya-city (JP); Junichi UEHARA, Kariya-city (JP)

(21) Appl. No.: 19/456,337

(22) Filed: Jan. 22, 2026

Related U.S. Application Data
(63) Continuation of application No. PCT/JP2024/025364, filed on Jul. 12, 2024.

(30) Foreign Application Priority Data
Jul. 24, 2023 (JP) 2023-120242

(51) Int. Cl. H10D 62/60; H10D 30/66; H10D 62/832; H10D 62/834; H10D 64/27; H10D 84/00; H10P 14/20

(52) U.S. Cl. CPC H10D 62/60; H10D 30/668; H10D 62/8325; H10D 62/834; H10D 84/143; H10P 14/2904; H10P 14/3444; H10D 64/513; H10D 64/518

(57) ABSTRACT

A silicon carbide wafer includes a silicon carbide substrate made of an n-type silicon carbide doped with an n-type impurity. The silicon carbide substrate contains boron, and a concentration of the boron in the silicon carbide substrate is 9.0×10¹⁶/cm³ or more.

### CROSS REFERENCE TO RELATED APPLICATIONS

The present application is a continuation application of International Patent Application No. PCT/JP2024/025364 filed on Jul. 12, 2024, which designated the U.S. and claims the benefit of priority from Japanese Patent Application No. 2023-120242 filed on Jul. 24, 2023. The entire disclosures of all of the above applications are incorporated herein by reference.

### TECHNICAL FIELD

The present disclosure relates to a silicon carbide (SiC) semiconductor wafer, an SiC semiconductor device, and a method for manufacturing an SiC single crystal.

### BACKGROUND

SiC has been put into practical use as a material of various semiconductor devices such as power devices for vehicles because SiC has excellent semiconductor characteristics. However, an SiC single-crystal substrate contains a wavy dislocation having a dislocation line on the (0001) plane referred to as a basal plane dislocation (hereinafter referred to as BPD).

### SUMMARY

According to an aspect of the present disclosure, a silicon carbide wafer includes a silicon carbide substrate made of an n-type silicon carbide doped with an n-type impurity. The silicon carbide substrate contains boron, and a concentration of the boron in the silicon carbide substrate is 9.0×10¹⁶/cm³ or more.

### BRIEF DESCRIPTION OF DRAWINGS

FIG. 1 is a perspective cross-sectional view of an SiC semiconductor device described in a first embodiment.

FIG. 2 is an explanatory diagram of a current path in the SiC semiconductor device.

FIG. 3A is an explanatory diagram illustrating states of holes and electrons near a built-in diode.

FIG. 3B is an explanatory diagram of defect growth caused by BPD near the built-in diode.

FIG. 4 is a binarized image diagram of a photoluminescence (PL) image in which a degree of expansion of SSF is confirmed through non-destructive inspection using a PL method.

FIG. 5 is a diagram illustrating a relationship between a B concentration, an SSF area occupancy rate, and an amount of warpage of an SiC wafer.

FIG. 6 is a diagram illustrating a change in hole density for each portion near a buffer layer when the B concentration in the SiC substrate is changed.

FIG. 7 is a diagram illustrating a change in hole density at an interface between an SiC substrate and a buffer layer relative to the B concentration.

FIG. 8A is a diagram illustrating a relationship between a B concentration at which SSF is 3% and conduction stress when there is no drop in n-type impurity concentration.

FIG. 8B is a diagram illustrating a relationship between the B concentration at which the SSF is 3% and the conduction stress when there is a drop in the n-type impurity concentration.

FIG. 9 is a diagram illustrating nitrogen (N) concentrations of the SiC substrate, the buffer layer, and a low-concentration layer.

FIG. 10A is a cross-sectional view illustrating a process of manufacturing the SiC semiconductor device illustrated in FIG. 1.

FIG. 10B is a cross-sectional view illustrating a process of manufacturing the SiC semiconductor device following FIG. 10A.

FIG. 10C is a cross-sectional view illustrating a process of manufacturing the SiC semiconductor device following FIG. 10B.

FIG. 10D is a cross-sectional view illustrating the process of manufacturing the SiC semiconductor device illustrated in FIG. 10C.

FIG. 10E is a cross-sectional view illustrating a process of manufacturing the SiC semiconductor device following FIG. 10D.

FIG. 10F is a cross-sectional view illustrating a process of manufacturing the SiC semiconductor device following FIG. 10E.

FIG. 10G is a cross-sectional view illustrating a process of manufacturing the SiC semiconductor device following FIG. 10F.

FIG. 11 is a diagram illustrating the amounts of warpage of a plurality of SiC wafer samples before an element formation process and after a process of forming a deep layer.

FIG. 12 is a view schematically illustrating a state in which an SiC wafer is sliced and cut out from an SiC ingot.

FIG. 13A is a diagram illustrating a relationship between the B concentration and the amount of warpage in a 6-inch wafer.

FIG. 13B is a diagram illustrating a relationship between the B concentration and the amount of warpage in an 8-inch wafer.

FIG. 14 is a perspective cross-sectional view of an SiC semiconductor device described in a second embodiment.

FIG. 15A is a cross-sectional view illustrating a process of manufacturing the SiC semiconductor device illustrated in FIG. 14.

FIG. 15B is a cross-sectional view illustrating a process of manufacturing the SiC semiconductor device following FIG. 15A.

FIG. 15C is a cross-sectional view illustrating a process of manufacturing the SiC semiconductor device following FIG. 15B.

FIG. 15D is a cross-sectional view illustrating the process of manufacturing the SiC semiconductor device illustrated in FIG. 15C.

FIG. 15E is a cross-sectional view illustrating a process of manufacturing the SiC semiconductor device following FIG. 15D.

FIG. 15F is a cross-sectional view illustrating a process of manufacturing the SiC semiconductor device following FIG. 15E.

FIG. 16 is a cross-sectional view illustrating a state in which an SiC ingot is grown in a growth crucible.

FIG. 17A is a graph of contents of various impurity elements contained in an SiC substrate.

FIG. 17B is a graph of contents of various impurity elements contained in a raw material powder.

FIG. 18A is a diagram illustrating a relationship between the concentration of each p-type impurity in the raw material powder and the concentration of each p-type impurity in the SiC substrate.

FIG. 18B is a table illustrating a relationship between the concentration of each p-type impurity in the raw material powder, the concentration of each p-type impurity in the SiC substrate, a ratio R_{P/S}, and a factor R_{S/P}.

FIG. 19 is a diagram examining changes in respective concentrations of p-type impurities for a normal crucible not subjected to high purification and a high-purity crucible subjected to high purification.

### DETAILED DESCRIPTION

When an epitaxial film is grown on an SiC single-crystal substrate to form an SiC semiconductor device including a switching element such as a metal-oxide-semiconductor field-effect transistor (MOSFET), a built-in diode is formed. When this SiC semiconductor device is applied to an inverter circuit or the like, and the built-in diode conducts in a bipolar operation due to a freewheel operation during switching, there is a possibility that the BPD expands into a Shockley-type stacking fault (hereinafter referred to as SSF). That is, holes passing near the BPD recombine with electrons in the n-type layer, and a large recombination energy is generated, so that the BPD expands into the SSF. Since the SSF is a defect having a larger occupied area than the BPD and more likely to degrade the electrical characteristics of the SiC semiconductor device, it is desirable to suppress expansion of the BPD into the SSF.

Meanwhile, as a related art, there is a technique for suppressing expansion of BPD into SSF. In manufacture of an SiC semiconductor device in which an epitaxial film is disposed on one surface of an SiC single-crystal substrate, a p-type impurity is incorporated during manufacture of an ingot used for forming an n-type SiC single-crystal substrate. As a result, crystallinity in the SiC single-crystal substrate is improved, and energy required for BPD to expand into SSF increases, thereby suppressing expansion of the BPD into the SSF.

However, although an effect of suppressing expansion of the BPD into the SSF can be obtained by incorporating a p-type impurity into the SiC single-crystal substrate, the effect cannot be sufficiently obtained depending on the current flowing through the built-in diode included in the SiC semiconductor device.

The present disclosure provides a silicon carbide semiconductor wafer, a silicon carbide semiconductor device, and a method for manufacturing a silicon carbide single crystal, which can suppress expansion of BPD into SSF.

According to an aspect of the present disclosure, an SiC wafer includes an SiC substrate made of an n-type SiC doped with an n-type impurity. The SiC substrate contains boron (B), and a concentration of the boron, i.e., B concentration in the SiC substrate is 9.0×10¹⁶/cm³ or more.

In such an SiC wafer, the B concentration is limited while B is introduced into the n-type SiC substrate, and the B concentration is 9.0×10¹⁶/cm³ or more. This makes it possible to suppress expansion of the BPD into the SSF.

According to another aspect of the present disclosure, an SiC semiconductor device includes: an SiC substrate made of n-type SiC doped with an n-type impurity; a low-concentration layer of an n-type disposed above the SiC substrate and having an n-type impurity concentration lower than an n-type impurity concentration of the SiC substrate; a deep layer of a p-type disposed above the low-concentration layer and having a plurality of linear portions, each of the linear portions having a longitudinal direction that extends in one direction in a planar direction of the SiC substrate; a junction field-effect transistor (JFET) portion of the n-type disposed above the low-concentration layer and having a linear portion sandwiched between the linear portions of the deep layer; a base region of the p-type disposed above the JFET portion and the deep layer; a source region of the n-type disposed in a surface layer portion of the base region; a trench gate structure including a gate insulating film disposed on a wall surface of a gate trench penetrating the source region and the base region, the trench gate structure including a gate electrode disposed on the gate insulating film; a source electrode electrically connected to the source region and the base region; and a drain electrode electrically connected to the SiC substrate. A pn-junction including the deep layer, the JFET portion, and the low-concentration layer constitutes a built-in diode, and a current density of a current flowing during a freewheel operation of the built-in diode is 11.6 A/mm² or more. The SiC substrate contains boron (B), and a B concentration in the SiC substrate is 9.0×10¹⁶/cm³ or more.

As described above, for applications in which a current density of a current flowing during a freewheel operation of a built-in diode is 11.6 A/mm² or more, the B concentration in the SiC substrate is set to 9.0×10¹⁶/cm³ or more. This makes it possible to suppress expansion of the BPD into the SSF.

According to a further another aspect of the present disclosure, a method for manufacturing an n-type SiC single crystal includes: placing a seed crystal for growing an SiC single crystal on one surface of a pedestal disposed in a growth crucible; and manufacturing an SiC ingot of the n-type SiC single crystal on a surface of the seed crystal by supplying a thermally decomposed SiC raw material, an n-type dopant, and boron (B) onto the surface of the seed crystal. In the manufacturing of the SiC ingot is grown so that a B concentration in the SiC ingot is 9.0×10¹⁶/cm³ or more.

As described above, during manufacture of the n-type SiC single crystal, the B concentration in the SiC ingot is set to 9.0×10¹⁶/cm³ or more. Therefore, when a vertical MOSFET in which a current density of a current flowing during a freewheel operation of a built-in diode is 11.6 A/mm² or more is manufactured using an SiC wafer obtained by slicing an SiC ingot, expansion of BPD into SSF can be suppressed.

Hereinafter, embodiments of the present disclosure will be described with reference to the drawings. In the embodiments, including other embodiments to be described below, portions that are the same or equivalent to one another are described with the same reference numerals assigned thereto.

### First Embodiment

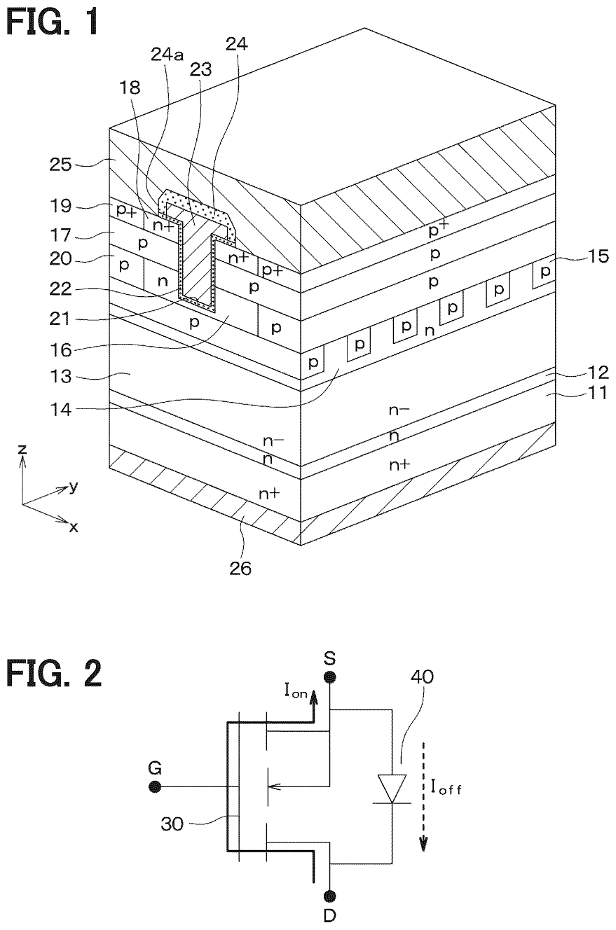

A first embodiment of the present disclosure will be described. First, a configuration of an SiC semiconductor device according to the present embodiment will be described with reference to FIG. 1.

### Configuration of SiC Semiconductor Device

In the SiC semiconductor device according to the present embodiment, an inversion-type vertical MOSFET having a trench gate structure, illustrated in FIG. 1, is formed as a semiconductor element. The vertical MOSFET illustrated in the drawings is formed in a cell region of the SiC semiconductor device, and an outer peripheral voltage-withstand structure is formed to surround the cell region, thereby constituting the SiC semiconductor device. However, only the vertical MOSFET is illustrated here. Hereinafter, as illustrated in FIG. 1, directions orthogonal to one another will be described as an X direction, a Y direction, and a Z direction. Specifically, a width direction of the vertical MOSFET is defined as an X direction, a front-back direction of the vertical MOSFET intersecting the X direction is defined as a Y direction, and a thickness direction or a depth direction of the vertical MOSFET, that is, a normal direction relative to an XY plane, is defined as a Z direction.

As illustrated in FIG. 1, an n⁺-type SiC substrate 11 doped with an n-type impurity is used for the SiC semiconductor device. The SiC substrate 11 is a portion constituting a drain region in a vertical MOSFET 30. The SiC substrate 11 has, for example, an off-angle of 0 to 8° relative to the (0001) Si plane, an n-type impurity concentration of nitrogen (N), phosphorus (P), or the like of 1.0×10¹⁹/cm³, and a thickness of a 350-μm specification or a 500-μm specification. The thickness of a 350-μm specification means a thickness in a range of 325 to 375 μm, and the thickness of a 500-μm specification means a thickness in a range of 475 to 525 μm.

The SiC substrate 11 is n-type, but contains at least boron (B) as a p-type impurity. As will be explained later, when it is assumed that a forward current flowing through a built-in diode 40 of a vertical MOSFET 30 in an equivalent circuit of FIG. 2 is 600 A or more and that a current density is 11.6 A/mm² or more, a B concentration is set to 9×10¹⁶/cm³ or more. When it is assumed that the forward current flowing through the built-in diode 40 is 800 A or more and that the current density is about 15 A/mm² or more, the B concentration is set to 1.5×10¹⁷/cm³ or more. The forward current assumed to flow through the built-in diode 40 is a current that can flow as a freewheel current during a freewheel operation when the SiC semiconductor device is applied to an inverter circuit or the like, in other words, the magnitude of conduction stress applied to the built-in diode 40. Hereinafter, the forward current assumed to flow through the built-in diode 40 is also referred to as conduction stress.

Preferably, the B concentration is 1.75×10¹⁷/cm³ or less when the thickness of the SiC substrate 11 is set to a 350-μm specification, and the B concentration is 7.2×10¹⁷/cm³ or less when the thickness is set to a 500-μm specification.

On the main surface of the SiC substrate 11, an n⁻-type buffer layer 12 made of SiC constituting a portion of the drift layer is formed. The buffer layer 12 is formed by epitaxial growth on the surface of the SiC substrate 11 and has an n-type impurity concentration that is an impurity concentration between the SiC substrate 11 and a low-concentration layer 13 to be described later. The buffer layer 12 has a thickness of, for example, about 1 μm and an n-type impurity concentration of 6.0×10¹⁷ to 1.5×10¹⁸/cm³. The n⁻-type low-concentration layer 13, made of SiC constituting a portion of the drift layer with a concentration lower than that of the SiC substrate 11, is formed on the buffer layer 12.

In the cell region, an n-type JFET portion 14 constituting a portion of a drift layer made of SiC is formed on the low-concentration layer 13. The low-concentration layer 13 is linked to the JFET portion 14 on the side opposite to the SiC substrate 11. Furthermore, in addition to the JFET portion 14, p-type deep layers 15 are formed over the low-concentration layer 13.

The JFET portion 14 and the deep layers 15 constitute a saturation current restriction layer, are both extended in the X direction as a longitudinal direction, and are alternately and repeatedly arranged in the Y direction. That is, when viewed from a normal direction relative to the main surface of the SiC substrate 11, at least a portion of the JFET portion 14 and the deep layers 15 are formed in a plurality of linear shapes, in other words, in stripe shapes, and are arranged in an alternating layout.

In the present embodiment, the JFET portion 14 is formed also below the deep layer 15. For this reason, the stripe-shaped portions of the JFET portion 14 are linked below the deep layer 15, whereas the respective stripe-shaped portions are disposed between the plurality of deep layers 15.

The deep layer 15 is constituted by an ion-implanted layer formed by ion-implanting a p-type impurity. As described above, the deep layers 15 are formed in a stripe shape, and the respective stripe-shaped linear portions of the deep layers 15 have a constant width, are arranged at equal intervals, and have a constant p-type impurity concentration in a depth direction, for example, 5×10¹⁷/cm³ or more. The deep layer 15 has a thickness of 1 μm or less as a dimension in the Z direction from the upper surface to the bottom.

Moreover, an n-type current distribution layer 16 constituting a portion of the drift layer made of SiC is formed on the JFET portion 14 and the deep layer 15. The current distribution layer 16 is a layer that allows current flowing through the channel of the vertical MOSFET 30 to diffuse in the Y direction, is formed in contact with a distal end side in a depth direction of a gate trench 21 to be described later, and has a higher n-type impurity concentration than the low-concentration layer 13, for example. However, the current distribution layer 16 does not necessarily have a higher impurity concentration than the low-concentration layer 13, and may have the same impurity concentration as the low-concentration layer 13, for example.

In the present embodiment, the drift layer includes the buffer layer 12, the low-concentration layer 13, the JFET portion 14, and the current distribution layer 16. However, the configuration of the drift layer is arbitrary, and for example, a structure not including the buffer layer may be adopted.

A p-type base region 17 made of SiC is formed on the current distribution layer 16. An n⁺-type source region 18 made of SiC is formed on the base region 17. The base region 17 has a p-type impurity concentration lower than that of the deep layer 15. The n-type impurity concentration of the source region 18 is higher than that of the current distribution layer 16.

A p⁺-type contact region 19 having a p-type impurity concentration higher than that of the base region 17 is formed to reach the base region 17 from the surface of the source region 18. In the present embodiment, the contact region 19 is configured in a linear shape with the Y direction as the longitudinal direction. Furthermore, a p-type linking layer 20 that connects the base region 17 and the deep layer 15 is formed below the contact region 19. The linking layer 20 is formed in a linear shape with the Y direction as a longitudinal direction together with the contact region 19, and is disposed on each side of the current distribution layer 16.

The contact region 19 and the linking layer 20 serve to link the deep layer 15 and the base region 17 to a source electrode 25 to be described later in order to fix the deep layer 15 and the base region 17 to the source potential.

Although the formation interval of the contact region 19 and the linking layer 20 is arbitrary, in the present embodiment, the contact region 19 and the linking layer 20 are formed on both sides of a trench gate structure to be described later. The widths of the contact region 19 and the linking layer 20 are arbitrary, but are equal to or less than an interval between adjacent trench gate structures.

Furthermore, a gate trench 21 having a predetermined width and a predetermined depth is formed to penetrate the source region 18 and the base region 17 and reach the current distribution layer 16. The base region 17 and the source region 18 described above are formed to be in contact with the side surface of the gate trench 21, and the contact region 19 is disposed to be separated from the gate trench 21. The gate trench 21 is formed in a linear layout in which the X direction is the width direction, the direction intersecting the longitudinal direction of the JFET portion 14 and the deep layer 15, here, the Y direction, is the longitudinal direction, and the Z direction is the depth direction. As illustrated in FIG. 1, a plurality of gate trenches 21 are formed in a stripe shape where a plurality of gate trenches are arranged at equal intervals in the X direction, and the base region 17, the source region 18, the contact region 19, and the linking layer 20 are arranged therebetween.

A portion of the base region 17 located on the side surface of the gate trench 21 is used as a channel region connecting the source region 18 and the current distribution layer 16 during operation of the vertical MOSFET 30, and the inner wall surface of the gate trench 21 including the channel region is covered with a gate insulating film 22. A gate electrode 23 made of doped polysilicon (poly-Si) is formed on the surface of the gate insulating film 22, and the gate insulating film 22 and the gate electrode 23 are disposed in the gate trench 21 to form a trench gate structure. Moreover, an interlayer insulating film 24 is formed to cover the gate electrode 23.

As illustrated in FIG. 1, a source electrode 25 and the like are formed on the surface of the source region 18 and the surface of the gate electrode 23 via the interlayer insulating film 24. The source electrode 25 is made of a plurality of metals, such as nickel/aluminum (Ni/Al). At least a portion of the plurality of metals in contact with n-type SiC, specifically, the source region 18 or the gate electrode 23 in the case of n-type doping, is made of a metal capable of ohmic contact with n-type SiC. At least a portion of the plurality of metals in contact with p-type SiC, specifically, the contact region 19, is made of a metal capable of ohmic contact with p-type SiC. The source electrode 25 is electrically insulated from the SiC portion by being formed on the interlayer insulating film 24, but is electrically in contact with the source region 18 and the contact region 19 through a contact hole 24a formed in the interlayer insulating film 24.

On the other hand, a drain electrode 26 electrically connected to the SiC substrate 11 is formed on the back surface side of the SiC substrate 11. With such a structure, an inversion-type n-channel vertical MOSFET 30 having a trench gate structure is configured. A plurality of such vertical MOSFETs 30 are arranged to form a cell region. Although not illustrated, the SiC semiconductor device is configured by forming an outer peripheral voltage-withstand structure, such as a guard ring, so as to surround the cell region.

In the SiC semiconductor device having such a configuration, the built-in diode 40 is formed within the vertical MOSFET 30 by a pn-junction between the low-concentration layer 13, the JFET portion 14, and the like and the deep layer 15, the linking layer 20, and the like.

The above is a basic configuration example of the SiC semiconductor device according to the present embodiment. As will be described later, this SiC semiconductor device is used, for example, in an inverter circuit for driving a three-phase motor using the vertical MOSFET 30 as a switching element.

### Defect Growth Caused by BPD

As described above, the SiC semiconductor device has a structure in which the vertical MOSFET 30 having a trench gate structure and the built-in diode 40 constituted by the pn-junction are provided in the cell region. BPD exists in the drift layer including the SiC substrate 11 and the buffer layer 12, and the like, and a defect caused by the BPD may occur in the SiC semiconductor device.

As illustrated in FIG. 2, an equivalent circuit of the SiC semiconductor device is illustrated as a circuit configuration including the MOSFET 30 and the built-in diode 40, and when the vertical MOSFET 30 is turned on, an on-current I_{ON} is generated from the drain electrode 26 to the source electrode 25. Note that “S”, “D”, and “G” in FIG. 2 correspond to the source electrode 25, the drain electrode 26, and the gate electrode 23, respectively. Specifically, when a predetermined voltage such as 20 V is applied to the gate electrode 23, a channel region is formed on the surface of the base region 17 in contact with the gate trench 21, and the on-current I_{ON} flows between the source electrode 25 and the drain electrode 26.

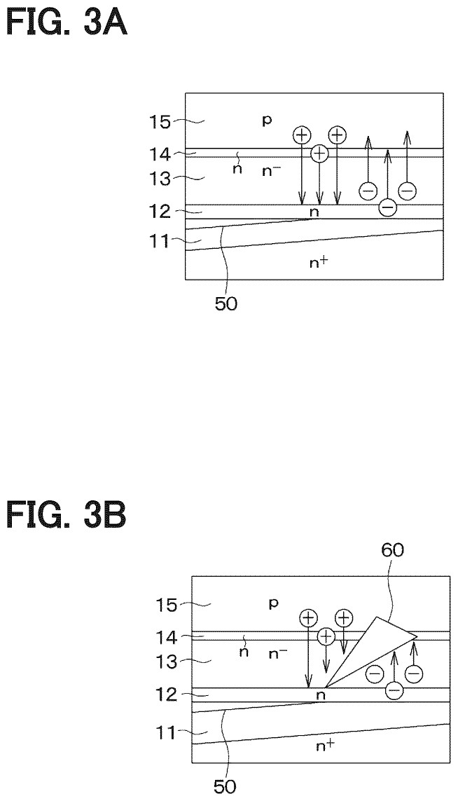

Thereafter, when the SiC semiconductor device is turned off, a reverse bias is applied, bringing the SiC semiconductor device into a reverse conduction state. Thus, the built-in diode 40 functions as a freewheel diode, and a freewheel current I_{OFF} flows through the built-in diode 40. At this time, as illustrated in FIG. 3A, holes diffused from the p-type layer side to the n-type layer side of the pn-junction constituting the built-in diode 40 are recombined with electrons in the n-type layer. Since the recombination energy between the hole and the electron is large, the BPD 50 expands to generate SSF 60 as illustrated in FIG. 3B. The SSF 60 expands as conduction stress on the built-in diode 40 accumulates. The SSF 60 has a larger occupied area than the BPD 50 and thus impedes the on-current I_{ON} and the freewheel current I_{OFF}. Since the SSF 60 expands according to conduction stress on the built-in diode 40, electrical characteristics after driving deteriorate in response to electrical characteristics immediately after manufacturing, that is, in a stage before occurrence of the SSF 60.

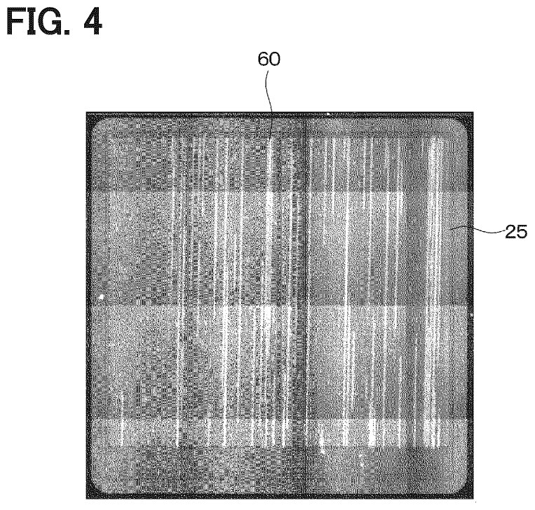

For example, a reverse bias was applied to the SiC semiconductor device of the present embodiment to allow the freewheel current I_{OFF} to flow to the built-in diode 40, and the state of the SSF 60 after conduction was confirmed. FIG. 4 is a binarized image of a photoluminescence (PL) image in which the degree of expansion of the SSF 60 was confirmed by non-destructive inspection using a PL method. A plurality of white-outlined portions linearly present in the upward-downward direction in FIG. 4 represent the SSF 60. As illustrated in FIG. 4, it can be seen that the SSF 60 is expanded in a portion that becomes the active region in the cell region of the SiC semiconductor device, that is, in a region where the source electrode 25 is disposed and conduction is performed. As the SSF 60 having a large occupied area expands in this manner, the on-current I_{ON} and the freewheel current I_{OFF} are impeded, causing deterioration in electrical characteristics.

To suppress this deterioration in electrical characteristics, it is necessary to provide an SiC semiconductor device with excellent diode conduction degradation characteristics that can suppress expansion of the BPD 50 into the SSF 60 even if stress accumulates in the built-in diode 40.

In particular, when the SiC semiconductor device is applied to an in-vehicle power card or the like, the amount of current flowing through one chip increases, making it inevitable that the built-in diode 40 turns on even when conduction is performed through the channel region. In addition, even during high-current operation in a freewheel mode where freewheel current flows, it is important to provide an SiC semiconductor device with excellent diode conduction degradation characteristics so as to suppress hole injection and suppress expansion of the SSF 60.

### B Concentration of SiC Substrate

For example, it is possible to obtain an effect of suppressing expansion of the BPD 50 into the SSF 60 by incorporating a p-type impurity into the n-type SiC single-crystal substrate. However, it has been confirmed that the effect of suppressing expansion of the BPD 50 into the SSF 60 cannot be sufficiently obtained simply by incorporating a p-type impurity. As a result of intensive studies, it has been found that the required effect of suppressing expansion of the BPD 50 into the SSF 60 can be obtained by adjusting the B concentration to a predetermined concentration or more while introducing B as a p-type impurity into the n⁺-type SiC substrate 11. Furthermore, it has been found that the B concentration required to obtain this effect varies depending on the magnitude of the freewheel current flowing in the forward direction of the built-in diode 40 when the SiC semiconductor device is applied to an inverter or the like, and that the larger the magnitude of the freewheel current, the higher the B concentration required.

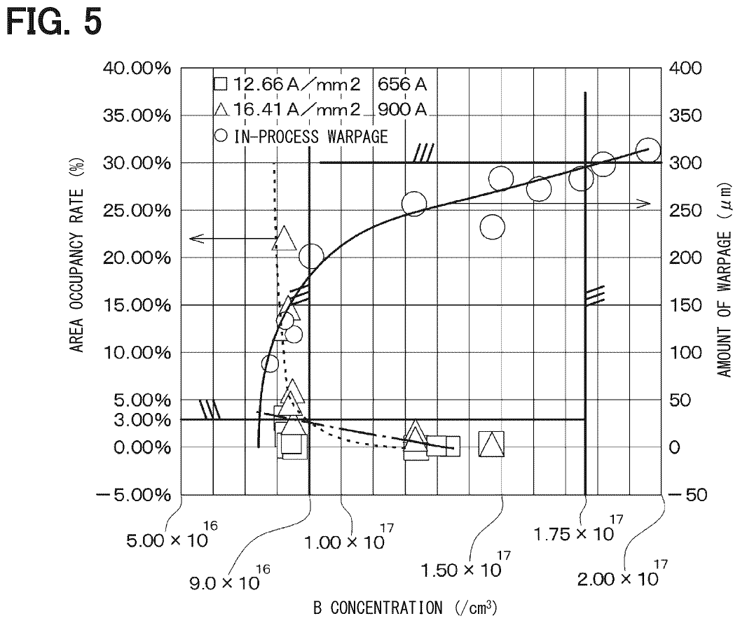

Specifically, when the SiC semiconductor device was applied to the inverter, a reverse bias was applied to the SiC semiconductor device to allow a forward current to flow through the built-in diode 40 assuming a case where conduction stress is 600 A or more and a case where conduction stress is 800 A or more. The B concentration in the SiC substrate 11 was then changed and an SSF area occupancy rate (%) after conduction was examined, to obtain the result illustrated in FIG. 5. The conduction stress of 600 A or more means that a current density, calculated by dividing a current value by an area of an active region where the current actually flows in the cell region where the vertical MOSFET 30 is formed, is 11.6 A/mm² or more. In the experiment, the current value that actually flowed assuming the conduction stress of 600 A or more was 656 A. The current density in this case was 12.66 A/mm². The conduction stress of 800 A or more means that the current density of the current flowing in the active region is 14.6 A/mm² or more. In the experiment, the actual current value that flowed assuming the conduction stress of 800 A or more was 900 A. The current density in this case was 16.41 A/mm².

As illustrated in this figure, in both the case where conduction stress is 600 A or more and the case where conduction stress is 800 A or more, the SSF area occupancy rate is reduced by introducing B into the SiC substrate 11. However, when the B concentration is less than 9.0×10¹⁶/cm³, the SSF area occupancy rate is high. This indicates that the effect of suppressing expansion of the BPD 50 into the SSF 60 has not been sufficiently obtained. Therefore, excellent diode conduction degradation characteristics cannot be obtained.

In contrast, in the case of the freewheel current of 600 A or more, here, in the case of 656 A, when the B concentration is at least 9.0×10¹⁶/cm³ or more, the SSF area occupancy rate has been able to be reduced to 3% or less. Also in the case of 800 A or more, here, in the case of 900 A, when the B concentration is at least 1.5×10¹⁷/cm³ or more, the SSF area occupancy rate has been able to be reduced to 3% or less. That is, the effect of suppressing expansion of the BPD 50 into the SSF 60 has been able to be sufficiently obtained.

From this result, to ensure diode conduction degradation characteristics, when the SiC semiconductor device is applied in a form in which the conduction stress of the built-in diode 40 is 600 A or more, the B concentration in the SiC substrate 11 is set to 9.0×10¹⁶/cm³ or more. When the SiC semiconductor device is applied in a form in which the conduction stress of the built-in diode 40 is 800 A or more, the B concentration in the SiC substrate 11 is set to 1.5×10¹⁷/cm³ or more. This makes it possible to provide an SiC semiconductor device that can obtain excellent diode conduction degradation characteristics. The larger the conduction stress, the higher the B concentration in the SiC substrate 11 necessary for obtaining excellent diode conduction degradation characteristics. Here, the current actually flowing in the experiment assuming the 600 A specification was 656 A, and the B concentration required at that time was 9.0×10¹⁶/cm³. However, in the case of 600 A, the B concentration required may be smaller than that, and it is sufficient that the B concentration be at least 9.0×10¹⁶/cm³ or more. Similarly, the current actually flowing in the experiment assuming the 800 A specification was 900 A, and the B concentration required at that time was 1.5×10¹⁷/cm³. However, in the case of 800 A, the B concentration required may be smaller than that, and it is sufficient that the B concentration be at least 1.5×10¹⁷/cm³ or more.

On the other hand, the higher the B concentration in the SiC substrate 11, the smaller the SSF area occupancy rate. However, it was found that if the B concentration in the SiC substrate 11 is excessively high, a problem occurs when the SiC substrate 11 is in a wafer state.

The SiC substrate 11 is formed by dicing an n⁺-type SiC wafer into chip units. Specifically, an element formation process is performed on an SiC wafer to form the vertical MOSFET 30 and the like, and then the wafer is diced into chip units to form an SiC semiconductor device, a portion of which that has been the SiC wafer is referred to as the SiC substrate 11.

The SiC wafer is a wafer of a specified inch size, for example, a 6-inch wafer or an 8-inch wafer, and is conveyed to various apparatuses such as an epitaxial growth apparatus and an ion implantation apparatus to perform an element formation process. At this time, depending on the amount of warpage of the SiC wafer, the SiC wafer cannot be sucked by a vacuum chuck provided in the apparatus, or the SiC wafer moves from a desired conveyance position during conveyance, preventing the element formation process from being performed favorably. Therefore, it is necessary to keep the amount of warpage of the SiC wafer within a specified range.

However, when the B concentration in the SiC substrate 11 was increased, the amount of warpage of the SiC wafer became large and could not be kept within a specified range, making it impossible to perform the element formation process favorably. The relationship between the amount of warpage of the SiC wafer and the B concentration was examined by conducting an experiment using a 6-inch wafer of a 350 μm thickness specification as the SiC wafer. FIG. 5 illustrates the results.

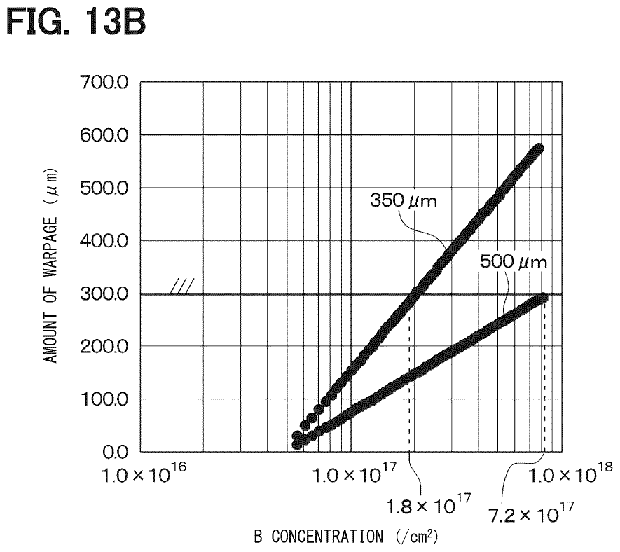

As illustrated in this figure, the higher the B concentration in the SiC substrate 11, the larger the amount of warpage. To favorably perform conveyance in the element formation process and suction of the SiC wafer by a vacuum chuck, the amount of warpage is preferably 300 μm or less. To satisfy this requirement, when the SiC wafer is a 6-inch wafer of a 350 μm specification, the B concentration is preferably 1.75×10¹⁷/cm³ or less as illustrated in FIG. 5 or FIG. 13A to be described later. Therefore, when a 6-inch wafer of a 350 μm thickness specification is used as the SiC wafer, the B concentration in the SiC substrate 11 is 1.75×10¹⁷/cm³ or less.

When the SiC wafer is an 8-inch wafer, similar experiments were performed when the thickness is set to a 350-μm specification and when the thickness is set to a 500-μm specification. As a result, as illustrated in FIG. 13B to be described later, it has been confirmed that the B concentration in the SiC substrate 11 is preferably 1.8×10¹⁷/cm³ or less when the thickness is set to the 350-μm specification, and is preferably 7.2×10¹⁷/cm³ or less when the thickness is set to the 500-μm specification.

That is, regardless of whether the SiC wafer is a 6-inch wafer or an 8-inch wafer, in the case of the 350-μm thickness specification, the amount of warpage can be suppressed so as not to affect conveyance by setting the B concentration in the SiC substrate 11 to 1.75×10¹⁷/cm³ or less. When the SiC wafer is an 8-inch wafer, in the case of the 500-μm thickness specification, the amount of warpage can be suppressed by setting the B concentration in the SiC substrate 11 to 7.2×10¹⁷/cm³ or less. Therefore, the B concentration in the SiC substrate 11 is set to satisfy these requirements.

The “amount of warpage” here means the magnitude of warpage that occurs during the element formation process. The “amount of warpage” is calculated as a difference in height between the highest position and the lowest position on one surface of the SiC wafer when the SiC wafer is placed on a plane. Usually, and SiC wafer is not in a completely flat state and has slight warpage even at an initial stage before an element formation process is performed. During conveyance of the SiC wafer, not only warpage occurring during the element formation process but also initial warpage of the SiC wafer is added. However, it is difficult to completely eliminate the initial warpage, and even if the warpage can be reduced, warpage of about 200 μm occurs when the warpage is large. For this reason, it is necessary to adjust the amount of warpage so as not to hinder execution of the element formation process even when initial warpage is added. The B concentration in the SiC substrate 11 is specified so that the amount of warpage is within a range that does not hinder execution of the element formation process.

In addition, it has been confirmed that, when the built-in diode 40 is caused to perform bipolar operation by a freewheel operation, hole injection into the SiC substrate 11 is suppressed when the hole density at an interface between the SiC substrate 11 and the buffer layer 12 is suppressed to 1.2×10¹⁶/cm³ or less. When the B concentration in the SiC substrate 11 is set in the range described above as in the present embodiment, it is also possible to satisfy the condition that the hole density at the interface between the buffer layer 12 and the low-concentration layer 13 is suppressed to 1.2×10¹⁶/cm³ or less.

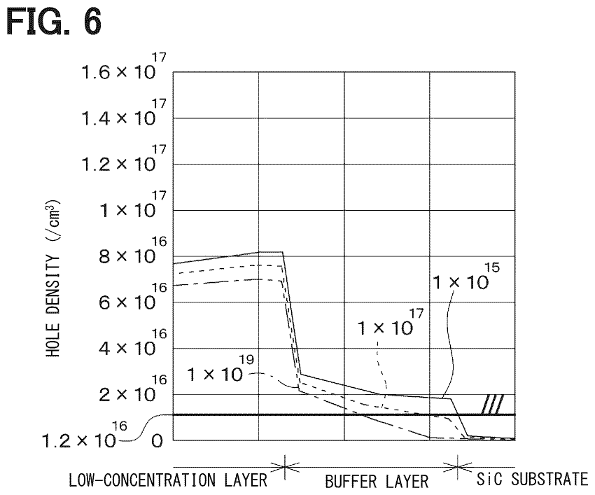

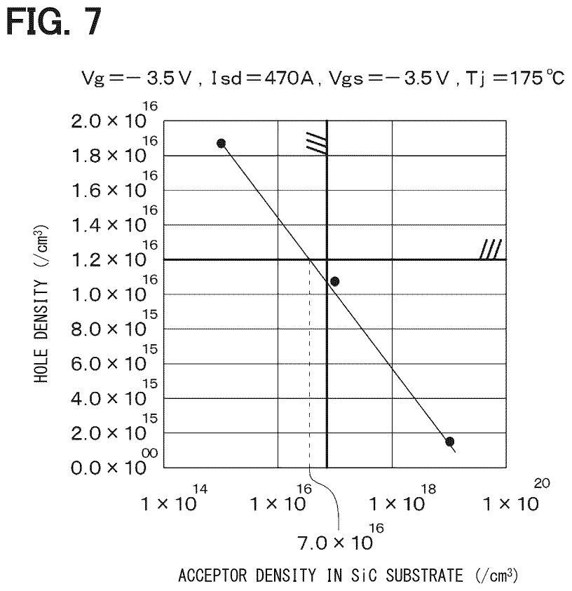

By simulation, in the case where the conduction stress of the built-in diode is set to 600 A or more, when a trap site by an acceptor assuming B is formed in the SiC substrate 11, a change in hole density at each portion was confirmed. Specifically, with the B concentration in the SiC substrate 11 set to 1.0×10¹⁵/cm³, 1.0×10¹⁷/cm³, and 1.0×10¹⁹/cm³, a change in hole density relative to each portion near the buffer layer 12 was examined. FIG. 6 illustrates the results. FIG. 7 is a diagram obtained by plotting and linearly approximating the hole density at the interface between the SiC substrate 11 and the buffer layer 12 at each of the B concentrations used in the simulation. Measurement conditions are as follows: gate voltage Vg=3.5 V, source-drain current Isd=470 A, gate-source voltage Vgs=−3.5 V, and temperature Tj=175° C.

As illustrated in FIGS. 6 and 7, when the B concentration in the SiC substrate 11 is set to 1.0×10¹⁵/cm³, the hole density is 1.8×10¹⁶/cm³ or more. However, when the B concentration in the SiC substrate 11 is set to 1.0×10¹⁷/cm³, the hole density is 1.1×10¹⁶/cm³ or less, and when the B concentration is set to 1.0×10¹⁹/cm³, the hole density is 2.0×10¹⁵/cm³ or less. As illustrated in FIG. 7, when linear approximation is performed, the hole density is 1.2×10¹⁶/cm³ when the B concentration is about 7.0×10¹⁶/cm³.

Therefore, in the case where the conduction stress of the built-in diode 40 is set to 600 A or more, as long as the B concentration in the SiC substrate 11 is set to 7.0×10¹⁶/cm³ or more, a flow of the hole current to the buffer layer 12 side can be suppressed. In the present embodiment, in the case where the conduction stress of the built-in diode 40 is set to 600 A or more, the B concentration in the SiC substrate 11 is 9.0×10¹⁶/cm³. Therefore, the hole density can be set to 1.2×10¹⁶/cm³ or less, and the hole current can be suppressed from flowing to the buffer layer 12 side, so that the BPD 50 in the SiC substrate 11 can be suppressed from expanding to the SSF 60.

The same simulation is performed when the conduction stress of the built-in diode 40 is 800 A or more. Also in this case, as described above, the hole density can be made 1.2×10¹⁶/cm³ or less as long as the B concentration is set to 1.5×10¹⁷/cm³ or more. Therefore, also in this case, similarly to the above, expansion of the BPD 50 in the SiC substrate 11 to the SSF 60 can be suppressed.

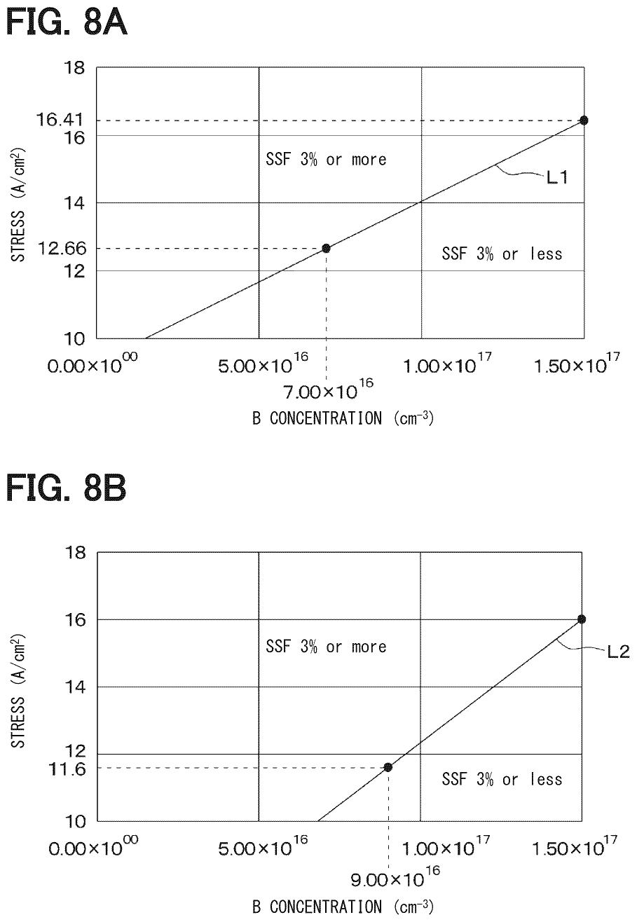

Here, as described above, in the present embodiment, in the case where the conduction stress of the built-in diode 40 is set to 600 A or more, the B concentration in the SiC substrate 11 is set to 9.0×10¹⁶/cm³. However, the above effect can be obtained as long as the B concentration is set to 7.0×10¹⁶/cm³ or more. In addition, in the case where the conduction stress of the built-in diode 40 is set to 800 A or more, the above effect can be obtained by setting the B concentration to 1.5×10¹⁷/cm³ or more. These values are expressed as the B concentrations of the SiC substrate 11 in two forms of the magnitude of the forward current flowing through the built-in diode 40, in other words, the magnitude of the conduction stress of 600 A or more and 800 A or more, but can be quantified as the B concentration relative to the magnitude of the conduction stress. As illustrated in FIG. 8A, a straight line L1 can be drawn connecting two plots of a B concentration of 7.0×10¹⁶/cm³ when the conduction stress is 12.66 A/mm² and a B concentration of 1.5×10¹⁷/cm³ when the conduction stress is 16.41 A/mm². The straight line L1 is a boundary line at which the SSF area occupancy rate becomes 3% after application of conduction stress. Therefore, by setting the B concentration in the SiC substrate 11 relative to the assumed conduction stress such that a point representing the relationship between the B concentration in the SiC substrate 11 and the magnitude of the conduction stress is located in the region on the right side of the straight line L1, it is possible to suppress expansion of the BPD 50 into the SSF 60.

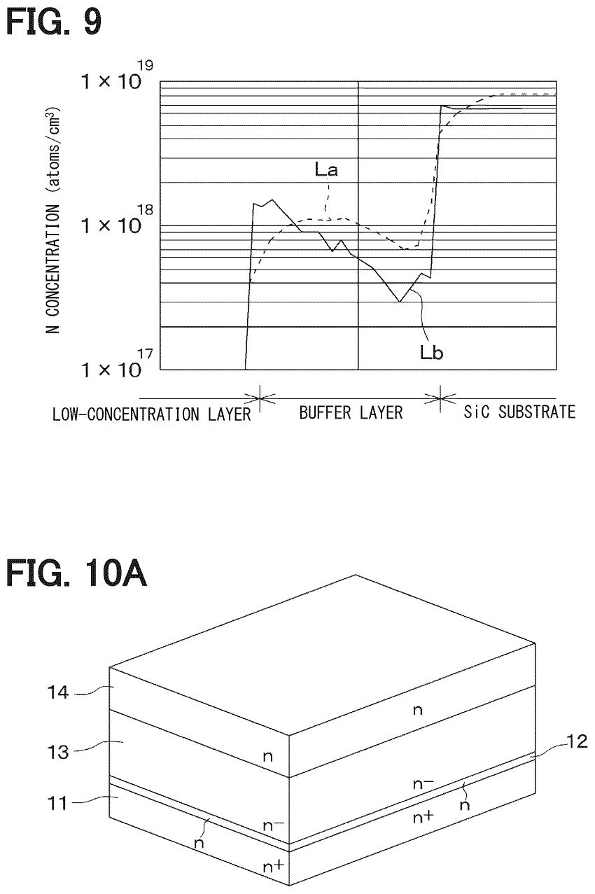

Although it is possible to suppress expansion of the BPD 50 into the SSF 60 by adjusting the B concentration in the SiC substrate 11, it has been confirmed that the n-type impurity concentration in the buffer layer 12 may also affect expansion of the BPD 50 into the SSF 60. Specifically, as indicated by a broken line La in FIG. 9, the SiC substrate 11, the buffer layer 12, the low-concentration layer 13, and the concentration of N doped as an n-type impurity are sequentially decreased in stages depending on the location. The buffer layer 12 has a concentration profile in which the n-type impurity concentration is 6.0×10¹⁷ to 1.5×10¹⁸/cm³ and in which a concentration distribution in the thickness direction is reduced. For example, a target value of 1.0×10¹⁸/cm³ is set, with a range of ±0.5×10¹⁸/cm³. However, as indicated by a solid line Lb, the n-type impurity concentration of the buffer layer 12 on the SiC substrate 11 side may drop to less than 6.0×10¹⁷/cm³. In this case, the ratio at which the BPD 50 expands into the SSF 60 may become higher than that in the case of the concentration profile of the broken line La. Therefore, it is preferable that the n-type impurity concentration of the buffer layer 12 be within a concentration range of ±50% relative to a target value, and that no drop in the n-type impurity concentration occur. However, although it is preferable that no drop occur, even if a drop occurs, it is also possible to cope by specifying a boundary line at which the SSF area occupancy rate becomes 3% after application of conduction stress. For example, it was confirmed that, when conduction stress was 11.6 A/mm², the B concentration was desirably 9×10¹⁶/cm³ or more. It was also confirmed that, when conduction stress was 16.0 A/mm² or more, the B concentration was desirably 1.5×10¹⁷/cm³ or more. In this case, as illustrated in FIG. 8B, a straight line L2 can be drawn connecting two plots of a B concentration of 9.0×10¹⁶/cm³ when the conduction stress is 11.6 A/mm² and a B concentration of 1.5×10¹⁷/cm³ when the conduction stress is 16.0 A/mm². It is sufficient that the straight line L2 be used as a boundary line where the SSF area occupancy rate becomes 3% after application of conduction stress.

### Method for Manufacturing SiC Semiconductor Device

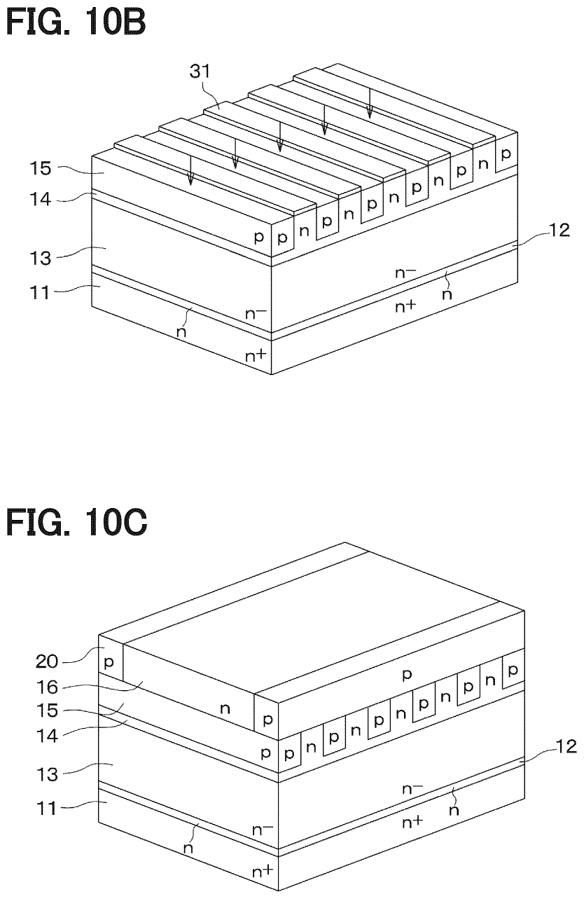

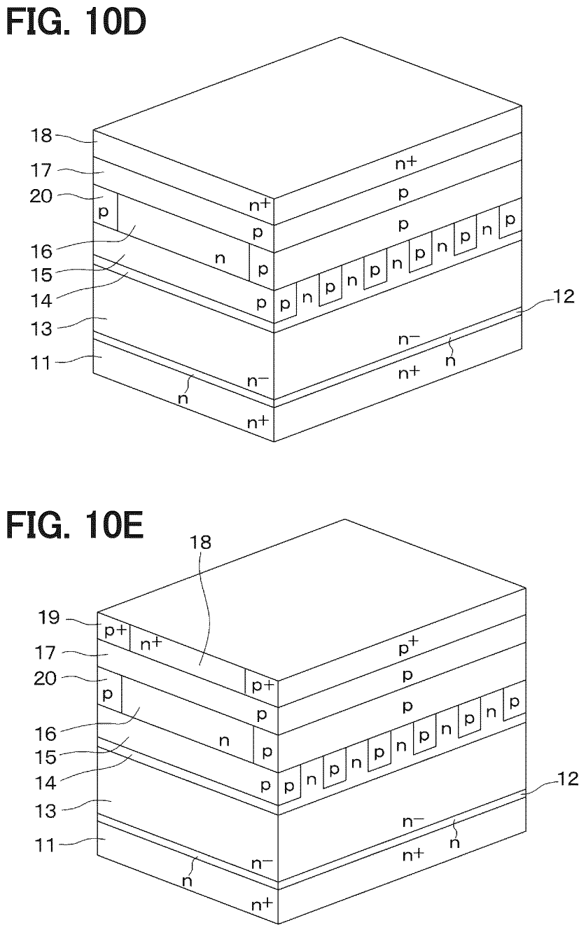

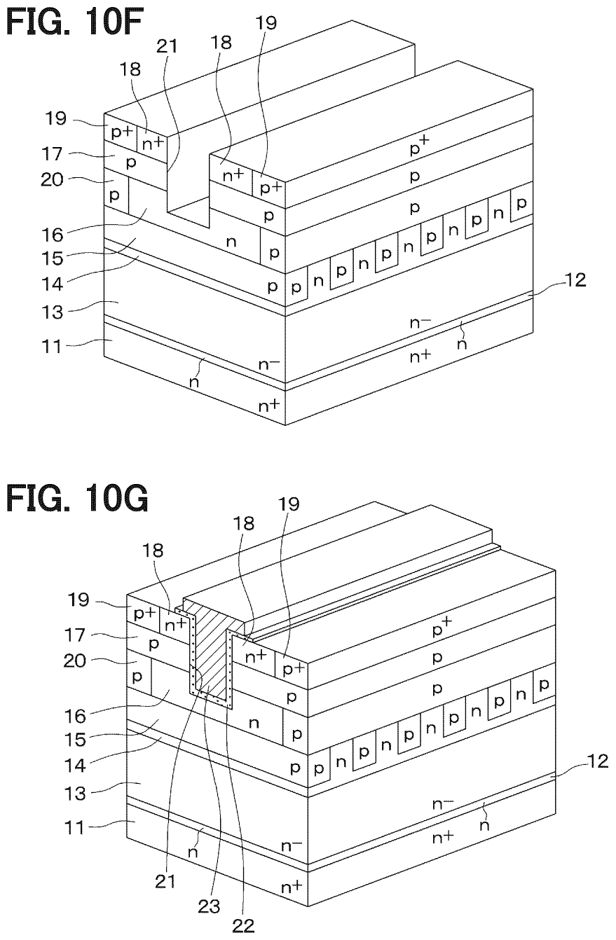

Next, a method for manufacturing the SiC semiconductor device according to the present embodiment will be described with reference to FIGS. 10A to 10G. FIGS. 10A to 10G are cross-sectional perspective views illustrating manufacturing processes in progress for the portion corresponding to FIG. 1.

### Process Illustrated in FIG. 10A

First, an SiC wafer for constituting the n⁺-type SiC substrate 11 is prepared. For the SiC wafer prepared at this time, when the conduction stress is 600 A or more, the B concentration is set to 9.0×10¹⁶/cm³ or more, and when the conduction stress is 800 A or more, the B concentration is set to 1.5×10¹⁷/cm³ or more. In addition, for the SiC wafer to be prepared, when a wafer of a 350-μm thickness specification is used, the B concentration is preferably 1.75×10¹⁷/cm³ or less in consideration of the amount of warpage. When a wafer of a 500-μm thickness specification is used, the B concentration is preferably 7.2×10¹⁷/cm³ or less in consideration of the amount of warpage.

An epitaxial film is grown on the surface of the SiC substrate 11 to form the buffer layer 12 and the low-concentration layer 13 made of SiC. Next, a mask (not illustrated) is formed on the surface of the low-concentration layer 13, and the mask is patterned by photolithography or the like so as to open a region scheduled for formation of the JFET portion 14. Specifically, the mask is patterned so as to open only a cell region. An n-type impurity such as N or P is ion-implanted and heat-treated from above the mask to form the JFET portion 14. Thereafter, the mask is removed. As the mask, for example, a low-temperature oxide (LTO) film or the like is used. In the present embodiment, masks are also used in a process to be described later, but for example, an LTO film or the like is used for each mask.

### Process Illustrated in FIG. 10B

A mask 31 is formed, and the mask 31 is patterned by photolithography or the like so as to open a region scheduled for formation of the deep layer 15. A p-type impurity such as Al is ion-implanted and heat-treated from above the mask 31 to form the deep layer 15.

### Process Illustrated in FIG. 10C

A current distribution layer 16 made of SiC is epitaxially grown on the low-concentration layer 13, the JFET portion 14, and the deep layer 15. As a result, a drift layer including the buffer layer 12, the low-concentration layer 13, the JFET portion 14, and the current distribution layer 16 is formed.

Next, a mask (not illustrated) is formed, and the mask is patterned by photolithography or the like so as to open a region scheduled for formation of the linking layer 20. A p-type impurity such as Al is ion-implanted and heat-treated from above the mask to form the linking layer 20. At this time, the linking layer 20 is extended in a direction intersecting the extending direction of the deep layer 15. For this reason, even if there is a slight positional deviation during formation of the linking layer 20, it is possible to suppress occurrence of a defect where the deep layer 15 and the linking layer 20 are not connected.

### Process Illustrated in FIG. 10D

A p-type impurity layer is epitaxially grown on the current distribution layer 16 and the linking layer 20 to form the base region 17. Subsequently, an n-type impurity layer is epitaxially grown on the base region 17 to form the source region 18.

### Process Illustrated in FIG. 10E

A mask (not illustrated) is formed, and the mask is patterned by photolithography or the like so as to open a region scheduled for formation of the contact region 19. Furthermore, a p-type impurity such as Al is ion-implanted and heat-treated from above the mask to form the contact region 19.

### Process Illustrated in FIG. 10F

After a mask (not illustrated) is formed, the mask is patterned so as to open a region scheduled for formation of the gate trench 21. Anisotropic etching is performed, and isotropic etching or sacrificial layer oxidation is performed as necessary to form the gate trench 21.

### Process Illustrated in FIG. 10G

The gate insulating film 22 is formed at a place including the inside of the gate trench 21 by thermal oxidation or chemical vapor deposition (CVD). Subsequently, a polysilicon layer doped with an n-type impurity is formed on the surface of the gate insulating film 22, and thereafter, an etch-back process or the like is performed so that the gate insulating film 22 and the gate electrode 23 remain in the gate trench 21. Thus, a trench gate structure is formed.

The subsequent processes, though not illustrated, include forming the interlayer insulating film 24, forming the contact hole 24a, forming the source electrode 25 and the gate wiring, and forming the drain electrode 26 on the back surface side of the SiC substrate 11. As a result, the SiC semiconductor device of the present embodiment is manufactured.

For a vertical device represented by an SiC power MOSFET, as compared with an Si device, it is possible to produce a high-electric-field-tolerant device with a short distance in the vertical direction, that is, a distance in the Z-axis direction corresponding to thickness. In SiC, impurities may not diffuse as in Si, and there is a tendency to increase an impurity concentration by increasing a dose of ion implantation during formation of an impurity layer. To improve the breakdown voltage of the gate insulating film 22, it is necessary to increase the ion implantation depth for forming the deep layer 15, and ion implantation is performed at a high acceleration energy. For example, in the ion implantation process of the deep layer 15 described above, since ions are implanted to a relatively shallow position of 1 μm or less, high-acceleration ion implantation at a high ion implantation energy is performed even though the ion implantation energy is 1 MeV or lower.

When the ion implantation process of increasing the impurity concentration and increasing the implantation depth is performed, large warpage tends to occur in the SiC wafer for forming the SiC substrate 11. However, as a result of intensive studies, it has been found that the amount of warpage itself does not depend on the impurity concentration or the implantation depth in ion implantation, but depends on the B concentration in the SiC wafer, that is, the content of B incorporated during manufacture of an SiC ingot.

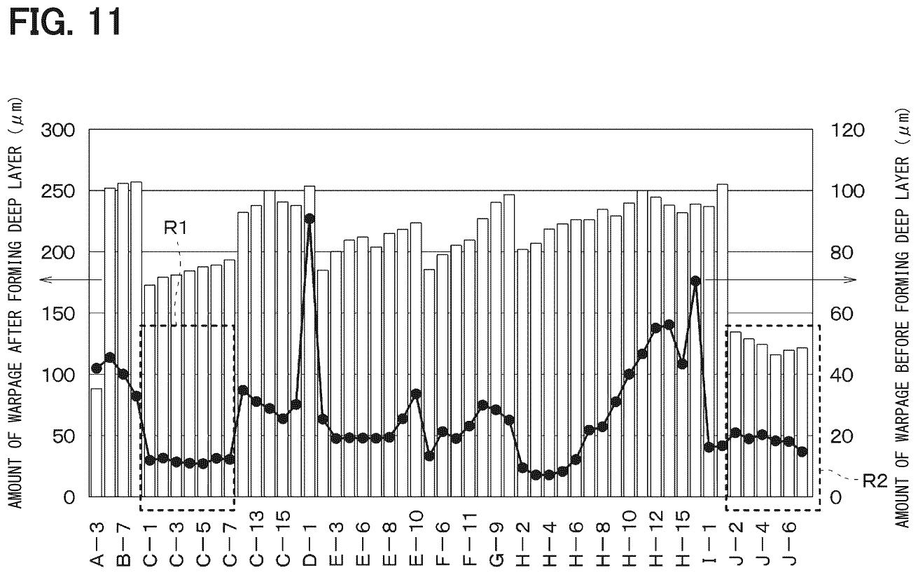

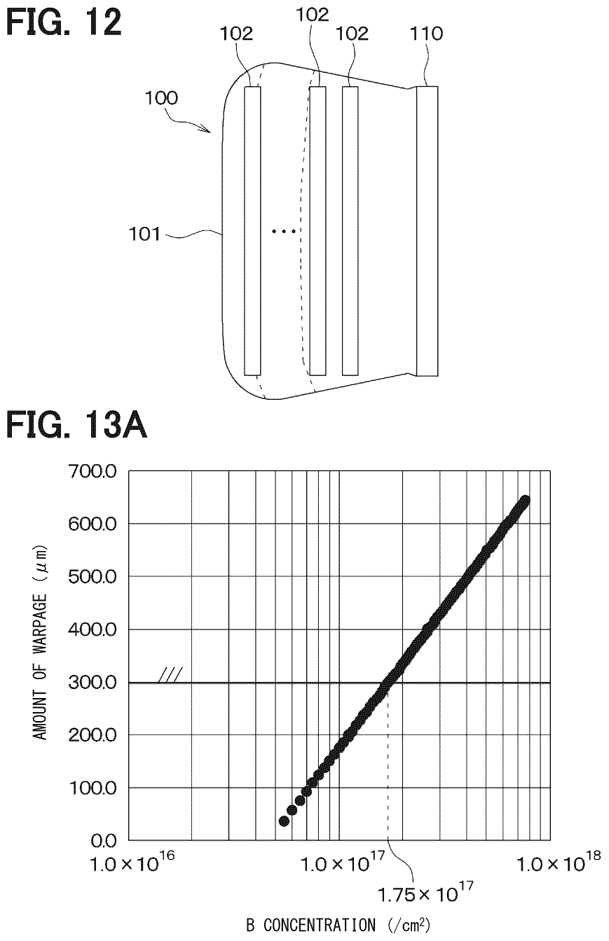

FIG. 11 illustrates results of measuring the amounts of warpage, after preparation of a plurality of SiC wafer samples, at each of a stage before an element formation process and a stage after a process of forming the deep layer 15. In FIG. 11, the horizontal axis indicates a sample number, where the initial English letters A to J denote an ingot number, and the subsequent numbers 1 to 15 indicate an order of cut SiC wafers. Those having the same ingot number indicate SiC wafers cut from the same SiC ingot. For example, A-1 indicates an SiC wafer cut as the “first” sheet from the SiC ingot having the number “A”. The order of the cut SiC wafers indicates numbers when the SiC wafers are cut in sequence from the distal end side of the SiC ingot. For example, it is assumed that an SiC ingot 100 illustrated in FIG. 12 is obtained. In this case, SiC wafers 102 are cut in sequence from a growth surface 101 side of the SiC ingot 100 toward a seed crystal 110 side, and the order of the cut SiC wafers 102 is represented by numbers.

In each of regions R1, R2 surrounded by broken lines in FIG. 11, when SiC wafers 102 obtained from the same SiC ingot 100 are compared with each other, the amounts of warpage are approximately the same both before the element formation process and after the process of forming the deep layer 15. However, when the SiC wafers 102 in the region R1 and the SiC wafers 102 in the region R2 are compared, the amounts of warpage after the process of forming the deep layer 15 are not approximately the same although the amounts of warpage before the element formation process are approximately the same. This is caused by the B concentrations in the SiC wafers 102, and since the B concentrations are approximately the same in the same SiC ingot 100, the amounts of warpage after the process of forming the deep layer 15 are approximately the same, whereas when the B concentrations differ, the amounts of warpage after formation of the deep layer 15 are not approximately the same.

As described above, it is found that the amount of warpage of the SiC wafer 102 during the element formation process depends on the B concentration in the SiC wafer 102, that is, the content of B incorporated during manufacture of the SiC ingot 100. Therefore, to control the amount of warpage, it is necessary to adjust the B concentration in the SiC wafer constituting the SiC substrate 11 in advance.

The relationship between the amount of warpage and the B concentration in the SiC substrate 11 was examined to obtain the result of FIG. 13A for a 6-inch wafer, and the result of FIG. 13B for an 8-inch wafer. For the 6-inch wafer, the case of a 350-μm thickness specification was examined. For the 8-inch wafer, the case of a 350-μm thickness specification and the case of a 500-μm thickness specification were examined. This relationship was primarily obtained by actual measurement, but for portions in which gaps are present between plots of a plurality of actual measurement values, values calculated by performing interpolation and extrapolation are used.

As illustrated in FIGS. 13A and 13B, in any size of the SiC wafer 102, the higher the B concentration in the SiC substrate 11, the larger the amount of warpage. In the case of the 6-inch wafer, when the amount of warpage was 300 μm, the B concentration was 1.75×10¹⁷/cm³. Similarly, in the case of the 8-inch wafer, when the amount of warpage was 300 μm, the B concentration was 1.8×10¹⁷/cm³ in the case of the 350-μm specification, and 7.2×10¹⁷/cm³ in the case of the 500-μm specification.

Therefore, as described in the process illustrated in FIG. 10A, in the case of the 350-μm thickness specification, the B concentration is preferably set to 1.75×10¹⁷/cm³ or less, and in the case of the 500-μm thickness specification, the B concentration is preferably set to 7.2×10¹⁷/cm³ or less. This makes it possible to obtain an SiC semiconductor device excellent in diode conduction characteristics, while also making it possible to suppress the amount of warpage of the SiC wafer 102 during the element formation process within a specified range. Therefore, it is possible to favorably perform conveyance in the element formation process and suction of the SiC wafer 102 by the vacuum chuck, and it is possible to smoothly perform the element formation process.

### Second Embodiment

A second embodiment will be described. The present embodiment changes the configuration of the vertical MOSFET 30 included in the SiC semiconductor device of the first embodiment, and other configurations are the same as those of the first embodiment. Accordingly, only portions different from those of the first embodiment will be described.

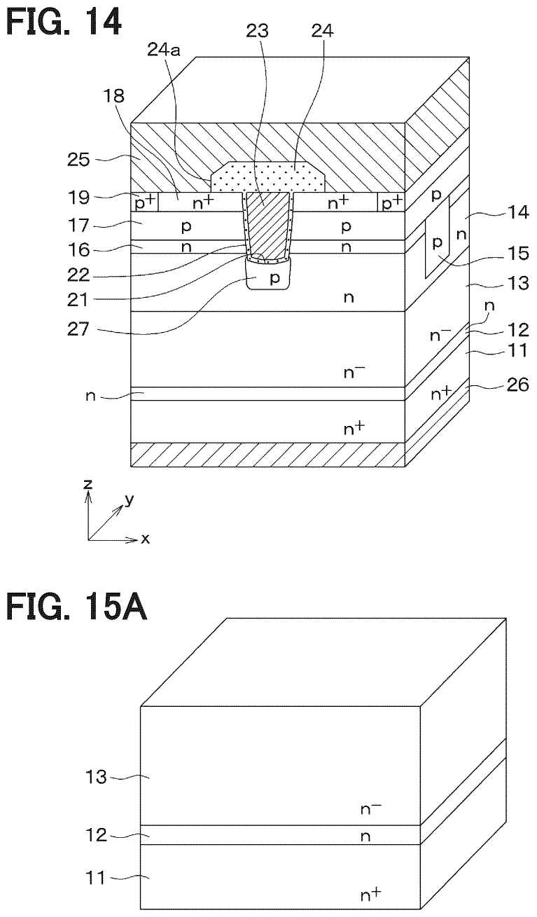

In the first embodiment, the deep layer 15 has been connected to the base region 17 via the linking layer 20. However, as illustrated in FIG. 14, in the present embodiment, the linking layer 20 is omitted, and the deep layer 15 is directly connected to the base region 17.

Also in the present embodiment, the current distribution layer 16 is formed to be in contact with the distal end side in the depth direction of the gate trench 21, but may be omitted. Since the current distribution layer 16 is provided on the portion of the JFET portion 14 located between the deep layers 15, the n-type impurity concentration in a surface layer portion of the JFET portion 14 may be set higher than that in a portion located below, and the surface layer portion may be used as the current distribution layer 16.

Furthermore, a p-type electric field relaxation layer 27 is provided along the bottom surface of the gate trench 21. The electric field relaxation layer 27 is constituted by, for example, a p-type layer having a lower impurity concentration than the deep layer 15. Specifically, the electric field relaxation layer 27 is formed along the longitudinal direction of the gate trench 21. That is, the electric field relaxation layer 27 is extended along the Y-axis direction intersecting the deep layer 15. The electric field relaxation layer 27 of the present embodiment is formed shallower than the JFET portion 14 and the deep layer 15, but may be formed to penetrate the JFET portion 14 and the deep layer 15 and have a bottom surface reaching the low-concentration layer 13.

As described above, the deep layer 15 may be directly connected to the base region 17. Also in the SiC semiconductor device having this structure, by setting the B concentration in the SiC substrate 11 to the concentration described in the first embodiment, expansion of the BPD 50 into the SSF 60 can be suppressed. In addition, by setting the B concentration in consideration of the amount of warpage, the amount of warpage of the SiC wafer 102 during the element formation process can be suppressed within a specified range.

In the case of the structure of the present embodiment, the distance from the bottom of the deep layer 15 to the bottom of the gate insulating film 22 is shorter than that in the first embodiment, raising concern about electric field intrusion into the gate insulating film 22. However, since the electric field relaxation layer 27 is provided along the bottom surface of the gate trench 21, electric field intrusion into the gate insulating film 22 located at the bottom of the gate trench 21 can be suppressed, and breakdown of the gate insulating film can be suppressed. In addition, by forming the electric field relaxation layer 27 so as to be in contact with the bottom surface of the gate trench 21, the electrostatic capacitance between the gate electrode 23 and the drain electrode 26, that is, the feedback capacitance, can be reduced, and the switching speed can be improved. Moreover, by providing the electric field relaxation layer 27, electric field rise toward the JFET portion 14 disposed between the electric field relaxation layers 27 is suppressed, and the breakdown voltage can be improved.

The electric field relaxation layer 27 may be formed by being divided into a plurality of portions along the Y-axis direction. However, the electric field relaxation layer 27 is formed to be electrically connected to the base region 17 via the deep layer 15.

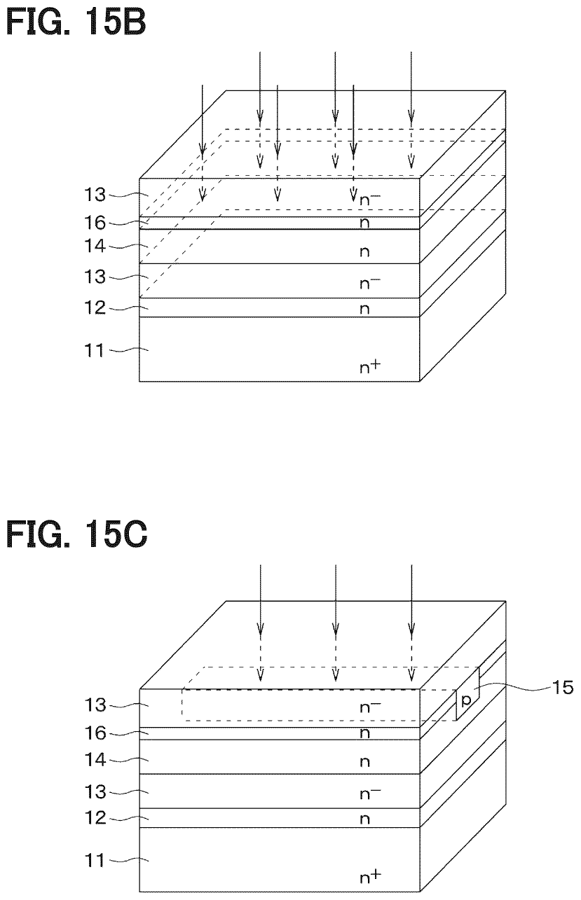

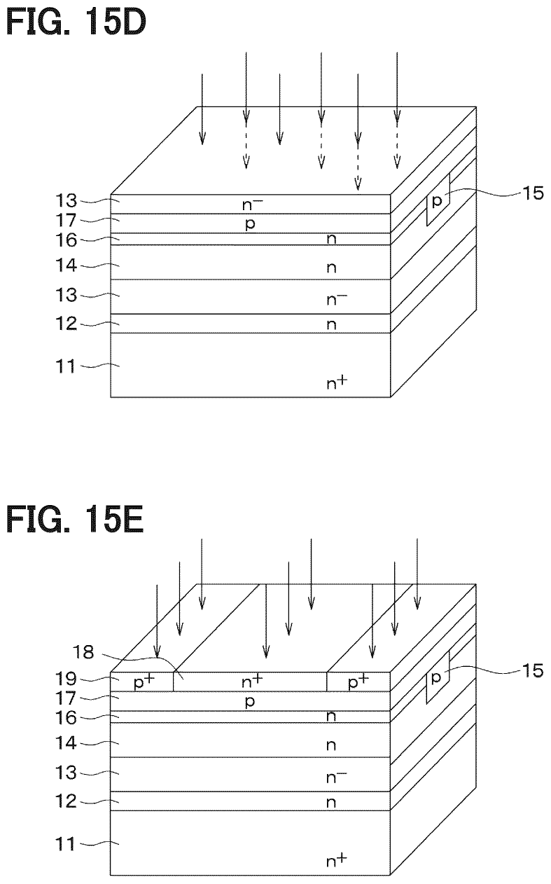

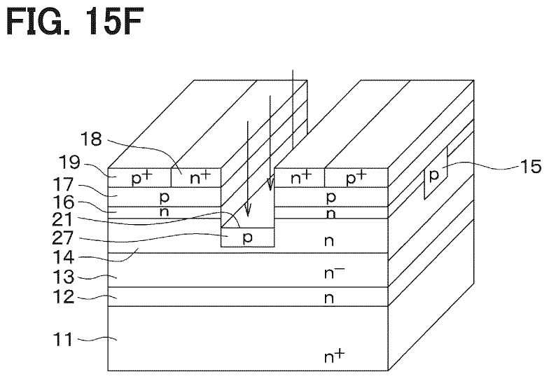

Next, a method for manufacturing the SiC semiconductor device according to the present embodiment will be described with reference to FIGS. 15A to 15F.

### Process Illustrated in FIG. 15A

The same process as the process illustrated in FIG. 10A of the first embodiment is performed to prepare the SiC wafer constituting the SiC substrate 11 having a desired B concentration is prepared, and thereafter, the buffer layer 12 and the low-concentration layer 13 are epitaxially grown. At this time, the thickness of the low-concentration layer 13 is set to the sum of the thicknesses of the JFET portion 14, the current distribution layer 16, the base region 17, the source region 18, and the contact region 19.

### Process Illustrated in FIG. 15B

After a mask (not illustrated) is formed, an n-type impurity such as N or P is ion-implanted into the surface of the low-concentration layer 13, and heat treatment is performed to form the JFET portion 14 and the current distribution layer 16 constituted by ion-implanted layers. For the JFET portion 14 and the current distribution layer 16, the dose amount of the n-type impurity and the ion implantation energy are adjusted separately.

### Process Illustrated in FIG. 15C

The same process as the process illustrated in FIG. 10B of the first embodiment is performed to form a mask so as to open a region scheduled for formation of the deep layer 15, although not illustrated. A p-type impurity such as Al is ion-implanted and heat-treated from above the mask to form the deep layer 15 constituted by an ion-implanted layer.

Here, in the process illustrated in FIG. 15B, the low-concentration layer 13 constituted by an epitaxial film is formed to have a large thickness. In this case, when the deep layer 15 is formed, the ion implantation energy is increased so that, for example, ion implantation to a deep position of 1 μm or more from the surface of the low-concentration layer 13 to be the source region 18 in a subsequent process can be performed. For example, the deep layer 15 is formed by performing high-acceleration ion implantation at a high ion implantation energy of 1 MeV or higher.

When the ion implantation process of increasing the impurity concentration and increasing the implantation depth is performed, large warpage tends to occur in the SiC wafer 102 for forming the SiC substrate 11. However, the amount of warpage does not depend on the impurity concentration or the implantation depth in the ion implantation, but depends on the B concentration in the SiC wafer 102, that is, the content of B incorporated during manufacture of the SiC ingot 100. Therefore, even when the ion implantation process at a high ion implantation energy of 1 MeV or higher is performed as in the present embodiment, the amount of warpage of the SiC wafer 102 during the element formation process can be suppressed within a specified range.

### Process Illustrated in FIG. 15D

After a mask in which a cell region (not illustrated) is opened is placed on a surface layer portion of the low-concentration layer 13, a p-type impurity such as Al is ion-implanted and heat treatment is performed. As a result, the base region 17 constituted by an ion-implanted layer is formed over the JFET portion 14, the deep layer 15, and the current distribution layer 16.

### Process Illustrated in FIG. 15E

After formation of a mask (not illustrated) that opens a region scheduled for formation of the source region 18, an n-type impurity such as N or P is ion-implanted into a surface layer portion of the low-concentration layer 13 from above the mask, and heat treatment is performed. Thus, the source region 18 constituted by an ion-implanted layer is formed on the base region 17. Subsequently, after formation of a mask (not illustrated) that opens a region scheduled for formation of the contact region 19, a p-type impurity such as Al is ion-implanted from above the mask and heat treatment is performed. Thus, the contact region 19 constituted by the ion-implanted layer is formed.

### Process Illustrated in FIG. 15F

After a mask (not illustrated) is formed, the mask is patterned so as to open a region scheduled for formation of the gate trench 21. Anisotropic etching is performed to form the gate trench 21. Furthermore, a mask (not illustrated) is used as it is, and a p-type impurity such as Al is ion-implanted into the bottom surface of the gate trench 21 and heat-treated to form the electric field relaxation layer 27.

The subsequent processes are the same as the processes after FIG. 10G illustrated in the first embodiment. In this way, the SiC semiconductor device of the present embodiment is manufactured.

As described above, in the present embodiment, the ion implantation energy in the ion implantation process is higher than that in the first embodiment, but the amount of warpage of the SiC wafer 102 can be set within a specified range. This makes it possible to favorably perform conveyance in the element formation process and suction of the SiC wafer 102 by the vacuum chuck, and to smoothly perform the element formation process.

### Third Embodiment

A third embodiment of the present disclosure will be described. The present embodiment specifies the relationship with other p-type impurities in addition to the B concentration in the SiC substrate 11 as compared with the first and second embodiments, and is the same as the first and second embodiments in other respects.

To prepare the SiC wafer 102 for constituting the SiC substrate 11, the SiC single crystal is grown in the growth crucible by the sublimation method or the gas growth method. Specifically, an SiC ingot made of SiC single crystal is manufactured and sliced to form the SiC wafer 102. The B concentration of the SiC ingot is set so that a desired B concentration is obtained in the SiC substrate 11. That is, the B concentration of the SiC ingot is set to 9.0×10¹⁶/cm³ or more when the conduction stress is 600 A or more, and is set to 1.5×10¹⁷/cm³ or more when the conduction stress is 800 A or more. Moreover, in consideration of the amount of warpage, the B concentration of the SiC ingot is adjusted to be 1.75×10¹⁷/cm³ or less in the case of a 350-μm specification, and to be 7.2×10¹⁷/cm³ or less in the case of a 500-μm specification. It has been found that, depending on the element ratio of the SiC raw material used for growth of the SiC single crystal, the element ratio of the p-type impurity elements contained in the SiC substrate 11 is eventually determined.

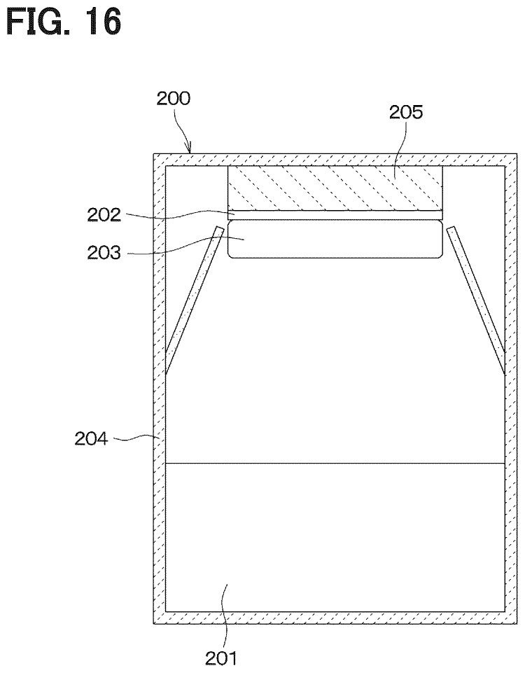

As an example, a case where a crystal growth experiment by the sublimation method is performed using the SiC single crystal manufacturing apparatus 200 illustrated in FIG. 16 will be described. In the sublimation method, an SiC ingot 203 is manufactured on a surface of a seed crystal 202 made of SiC single crystal by heating and sublimating a raw material powder 201 obtained by powdering SiC as an SiC raw material. In the experiment, a growth crucible 204 made of graphite or the like was inductively heated to thermally decompose the raw material powder 201 placed below a pedestal 205 at about 2500° C., and the SiC ingot 203 was grown on the surface of the seed crystal 202 attached to the pedestal 205. For the raw material powder 201, in addition to the SiC powder obtained by powdering SiC, B powder containing boron carbide or boron nitride was introduced as a B raw material. In addition, the n-type SiC ingot 203 is obtained by introducing N₂ gas as an n-type dopant.

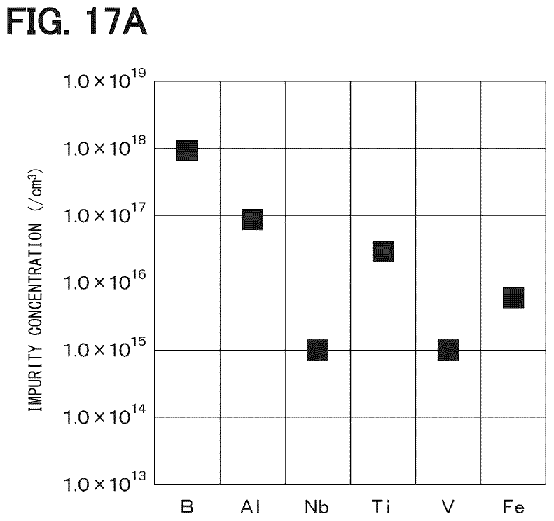

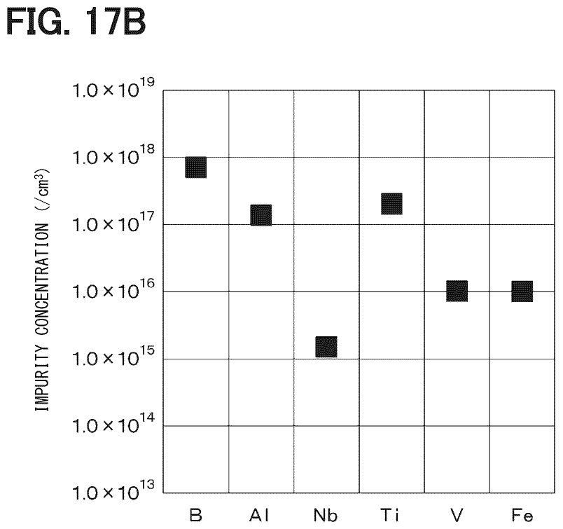

In addition to B, the raw material powder 201 contains various impurities including p-type impurity elements, and their content depends on the purity of the raw material powder 201. Through experiments, contents of various p-type impurity elements contained in the raw material powder 201, as well as contents of various p-type impurity elements contained in the SiC substrate 11 obtained by producing the SiC wafer 102 using the SiC ingot 203 manufactured using the raw material powder 201, were measured. FIG. 17A is a graph of the contents of various impurity elements contained in the SiC substrate 11, and FIG. 17B is a graph of the contents of various impurity elements contained in the raw material powder 201.

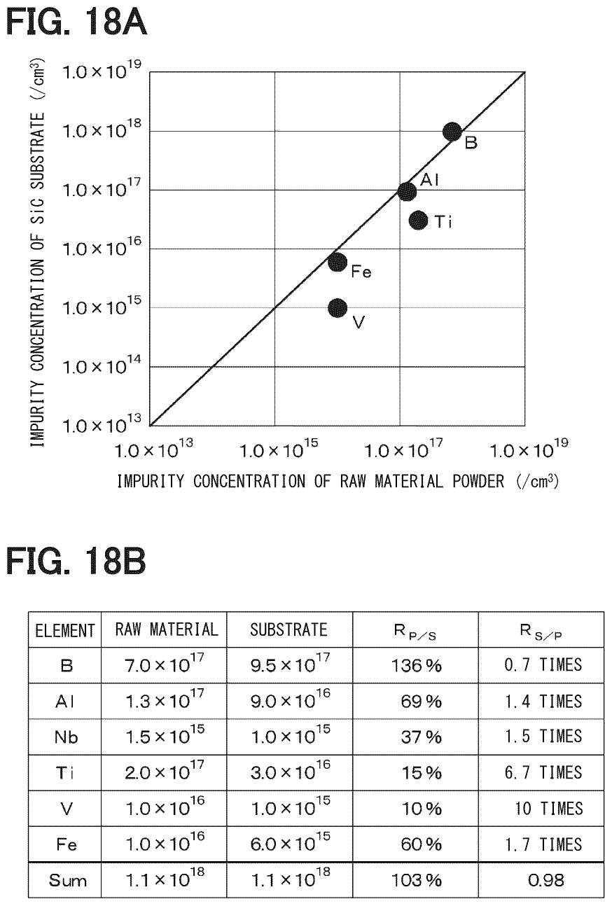

In addition, a ratio R_{P/S} when the p-type impurity element contained in the raw material powder 201 was incorporated into the SiC substrate 11, and a factor R_{S/P} of the p-type impurity content in the raw material powder 201 relative to the p-type impurity content in the SiC substrate 11, were examined. The ratio R_{P/S} and the factor R_{S/P} indicate ease of incorporation of an element into the SiC substrate 11. The element is more easily incorporated into the SiC substrate 11 as the ratio R_{P/S} increases and the factor R_{S/P} decreases. FIGS. 18A and 18B summarize the results.

As illustrated in FIG. 18B, when the B concentration in the raw material powder 201 was 7.0×10¹⁷/cm³, the B concentration in the SiC substrate 11 was 9.5×10¹⁷/cm³, the ratio R_{P/S} was 136%, and the factor R_{S/P} was 0.7 times. For p-type impurities, for example, Al (aluminum), Nb (niobium), Ti (titanium), V (vanadium), Fe (iron), and the like, results were also as illustrated in FIGS. 18A and 18B. As illustrated in FIG. 18B, although the ratio R_{P/S} and the factor R_{S/P} differ for each element, as illustrated in FIG. 18A, the ratio for each element approximates a straight line in which the content in the raw material powder 201 and the content in the SiC substrate 11 are in a 1:1 relationship. That is, the degree of content of each of the impurities in the raw material powder 201, in other words, the quality of the raw material powder 201, is important, and determination of the degree of content enables the B concentration and the like in the SiC substrate 11 to be adjusted.

For example, for B, when the factor R_{S/P} is set to 0.7 times, that is, the B concentration in the raw material powder 201 is set to 0.7 times the target value, the B concentration in the SiC substrate 11 can be set to the target value. Therefore, the SiC ingot 203 is grown with the B concentration in the raw material powder 201 set to about 0.7 times the target value of the B concentration in the SiC substrate 11. Similarly, for Al, the SiC ingot 203 is grown with the Al concentration in the raw material powder 201 set to about 1.4 times the target value. For Nb, the SiC ingot 203 is grown with the Nb concentration in the raw material powder 201 set to about 1.5 times the target value. For Ti, the SiC ingot 203 is grown with the Ti concentration in the raw material powder 201 set to about 6.7 times the target value. For V, the SiC ingot 203 is grown with the V concentration in the raw material powder 201 set to about 10 times the target value. For Fe, the SiC ingot 203 is grown with the Fe concentration in the raw material powder 201 set to about 1.7 times the target value. Thus, the concentrations of various p-type impurities in the SiC substrate 11 can be set to desired target values.

When the impurity concentration in the SiC substrate 11 has an upper limit value and the target value is set to be equal to or less than the upper limit value, the impurity concentration in the raw material powder 201 is set to be equal to or less than a value obtained by dividing the impurity concentration of the target value by the factor R_{S/P} of the impurity. Thus, the impurity concentration in the SiC substrate 11 can be set to a desired upper limit value or less. When the impurity concentration in the SiC substrate 11 has a lower limit value and the target value is set to be equal to or more than the lower limit value, the impurity concentration in the raw material powder 201 is set to be equal to or more than a value obtained by dividing the impurity concentration of the target value by the factor R_{S/P} of the impurity. Thus, the impurity concentration in the SiC substrate 11 can be set to a desired lower limit value or more.

Furthermore, concentrations of various p-type impurities were measured when the B concentration in the SiC substrate 11 was 7.0×10¹⁶ to 1.4×10¹⁷/cm³, and examination was made as to whether expansion of the BPD 50 into the SSF 60 is affected due to changes in concentrations of various p-type impurities other than B. Examination was also made as to whether the amount of warpage of the SiC wafer 102 is affected. As a result, it has been confirmed that expansion of the BPD 50 into the SSF 60 and the amount of warpage of the SiC wafer 102 are affected to a limited extent, and that adjustment can primarily be made to the B concentration. Specifically, contents of other impurities were measured when the B concentration in the SiC substrate 11 was set in a range in which the amount of warpage was within a specified range while expansion of the BPD 50 into the SSF 60 was suppressed. As a result, the total impurity concentration of the p-type impurities other than B was 2.3×10¹⁷/cm³ or less for the 6-inch wafer and 2.9×10¹⁷/cm³ or less for the 8-inch wafer. For both the 6-inch wafer and the 8-inch wafer, the Al concentration was 5.0×10¹⁵/cm³ or less, the Ti concentration was 1.0×10¹⁶/cm³ or less, the V concentration was 4.0×10¹⁵/cm³ or less, and the Fe concentration was 6.0×10¹⁶/cm³ or less. Therefore, when the total impurity concentration of the p-type impurities other than B is equal to or less than each of these concentrations, it was possible to keep the amount of warpage within a specified range while suppressing expansion of the BPD 50 into the SSF 60 by adjusting at least the B concentration to the range described in the first and second embodiments.

Here, the case of manufacturing the SiC ingot 203 by the sublimation method has been described as an example, but the SiC ingot 203 may be manufactured by the gas growth method. In the case of the gas growth method, a gas introduction port is provided in the bottom of the growth crucible 204, an exhaust port is provided in the upper portion or the side portion of the growth crucible 204, and the SiC ingot 203 is manufactured by introducing an SiC raw material gas, an n-type dopant gas, and a B dopant gas.

In the case of the sublimation method, after the raw material powder 201 is placed in the growth crucible 204, the state of the raw material powder 201 cannot be confirmed during growth, but in the case of the gas growth method, the introduced gases can be controlled. Therefore, the p-type impurity concentration containing B in the SiC ingot 203 is more easily controlled by the gas growth method than by the sublimation method. In practice, the SiC ingot 203 was manufactured by each of the sublimation method and the gas growth method, and the concentration of each p-type impurity was measured. When the deviation of the actual impurity concentration from the target value was confirmed, for the B concentration, the actual impurity concentration was closer to the target value in the gas growth method than in the sublimation method. For the other p-type impurities, the actual impurity concentration may be closer to the target value in the gas growth method, and conversely, the actual impurity concentration may be closer to the target value in the sublimation method. Therefore, in the case of controlling the B concentration with higher accuracy, it is preferable to use the gas growth method, whereas in the case of controlling the other p-type impurity concentrations, comparable control can be achieved with either the gas growth method or the sublimation method.

When the SiC ingot 203 is manufactured by the gas growth method, a B-containing gas is introduced into the growth crucible 204 in addition to the SiC raw material gas and the n-type dopant gas. For example, one of SiH₄, H₂SiCl₂, or HSiCl₃ as an Si raw material and one of C₃H₈ or C₂H₄ as a C raw material are introduced as the SiC raw material gas into the growth crucible 204. In addition, N₂ or the like is introduced as the n-type dopant gas, and the B-containing gas, such as BCl₃ or B₂H₃, is introduced. Therefore, it is possible to manufacture an ingot of SiC single crystal having the B concentration described above. At this time, an etching gas such as HCl or a carrier gas such as H₂ is introduced into the growth crucible 204, enabling optimization of the crucible atmosphere, suppression of polycrystal formation, and the like, whereby the SiC ingot 203 can be manufactured more favorably.

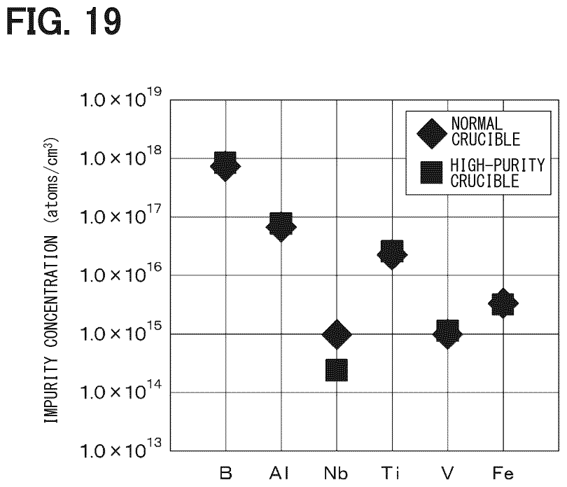

Furthermore, in the sublimation method, whether the purity of the growth crucible 204 affects the accuracy of the p-type impurity concentration was also measured. Specifically, when a Cl₂ gas or the like is supplied to the growth crucible 204 before the growth of the SiC ingot 203 to perform metal removal treatment, a constituent material of the growth crucible 204, for example, graphite or graphite coated with a high melting point metal, can be subjected to high purification. For each of the case where high purification was performed and the case where high purification was not performed, the SiC ingot 203 was manufactured, and the p-type impurity concentration in the SiC substrate 11 was measured when the SiC semiconductor device was manufactured using the SiC wafer 102 cut out from the manufactured SiC ingot 203. FIG. 19 illustrates the results, and it was confirmed that, regardless of whether high purification was performed, the difference in p-type impurity concentration in the SiC substrate 11 was small, and that in either case, the p-type impurity concentration could be controlled with high accuracy. Therefore, it is possible to control the p-type impurity concentration regardless of whether high purification is performed.

Here, in the case of manufacturing the SiC ingot 203 by the sublimation method, B raw material powder containing boron carbide or boron nitride as a B raw material was added to the raw material powder 201 in order to adjust the B concentration. In addition to this, for example, it is sufficient that aluminum carbide be added as an Al raw material when the Al concentration is adjusted, titanium carbide be added as a Ti raw material when the Ti concentration is adjusted, and tantalum carbide powder be added as Ta raw material when the Ta concentration is adjusted, to the raw material powder 201. Of course, when the concentrations of a plurality of p-type impurity elements are adjusted, a combination of the plurality of p-type impurity elements may be added to the raw material powder 201. Instead of the powder containing the p-type impurity element, a sintered body may be used.

As the raw material powder 201, only SiC having a high purity may be used, and a chloride gas, for example, BCl₃ in the case of a B raw material, or a hydride gas, for example, B₂H₃ in the case of a B raw material, may be introduced into the growth crucible 204 as a p-type dopant gas.

Moreover, in addition to the SiC powder having a fine particle size, SiC powder having a coarser particle size and having a B concentration of 1.2×10¹⁷/cm³ or more may be prepared, and the two powders may be stacked in two layers to be used as the raw material powder 201. Specifically, SiC powder having a fine grain size may be placed on SiC powder having a coarse grain size, and the p-type impurity element may be supplied to the growth surface of the SiC ingot 203 through gaps between particles of the SiC powder having a fine grain size.

### Other Embodiments

Although the present disclosure has been described in accordance with the embodiments described above, the present disclosure is not limited to the embodiments but also includes various modifications and variations within an equivalent range. In addition, various combinations and forms, as well as other combinations and forms including only one element, more than that, or fewer than that, are also within the scope and spirit of the present disclosure.

For example, in the third embodiment, the case where p-type impurities other than B are introduced during manufacture of the SiC ingot 203 has been described, but the introduction of p-type impurities other than B into the SiC ingot 203 may be prevented. For example, before the seed crystal 202 used for manufacture of the SiC ingot 203 is placed in the growth crucible, heat treatment is performed to remove the p-type impurities other than B in the raw material powder 201. At this time, by including B raw material powder containing boron carbide or boron nitride in the raw material powder 201, B sufficiently remains even after heat treatment, so that B is not completely removed. Alternatively, after heat treatment is performed to remove p-type impurities other than B from the raw material powder 201, B raw material powder containing boron carbide or boron nitride may be placed. After the removal of the p-type impurities other than B, the seed crystal 202 is placed in the growth crucible, and the SiC ingot 203 is manufactured, whereby the B concentration in the SiC ingot 203 can be set to a desired concentration while the concentrations of the p-type impurities other than B are minimized.

In each of the above embodiments, the 6-inch wafer and the 8-inch wafer have been exemplified as the SiC wafer 102, but the present disclosure can also be applied to wafers having different dimensions. Also in this case, regarding the B concentration that can suppress expansion of the BPD 50 into the SSF 60, it is sufficient that the B concentration be set to 9.0×10¹⁶/cm³ or more when the conduction stress is 600 A or more, and that the B concentration be set to 1.5×10¹⁷/cm³ or more when the conduction stress is 800 A or more.

What is claimed is:

1. A silicon carbide wafer comprising a silicon carbide substrate made of an n-type silicon carbide doped with an n-type impurity, wherein
the silicon carbide wafer is a 6-inch wafer or an 8-inch wafer having a thickness of 325 μm to 375 μm, and
the silicon carbide substrate contains boron at a concentration of 9.0×10¹⁶/cm³ or more and 1.75×10¹⁷/cm³ or less in the silicon carbide substrate.

2. The silicon carbide wafer according to claim 1, wherein
the concentration of the boron is 1.5×10¹⁷/cm³ or more.

3. A silicon carbide wafer comprising a silicon carbide substrate made of an n-type silicon carbide doped with an n-type impurity, wherein
the silicon carbide wafer is an 8-inch wafer having a thickness of 475 μm to 525 μm, and
the silicon carbide substrate contains boron at a concentration of 9.0×10¹⁶/cm³ or more and 7.2×10¹⁷/cm³ or less.

4. The silicon carbide wafer according to claim 3, wherein
the concentration of the boron is 1.5×10¹⁷/cm³ or more.

5. A silicon carbide semiconductor device, comprising:
a silicon carbide substrate made of an n-type silicon carbide doped with an n-type impurity;
a low-concentration layer of an n-type disposed above the silicon carbide substrate and having an n-type impurity concentration lower than an n-type impurity concentration of the silicon carbide substrate;
a deep layer of a p-type disposed above the low-concentration layer and having a plurality of linear portions, each of the linear portions having a longitudinal direction that extends in one direction in a planar direction of the silicon carbide substrate;
a junction field-effect transistor (JFET) portion of the n-type disposed above the low-concentration layer and having a linear portion sandwiched between the linear portions of the deep layer;
a base region of the p-type disposed above the JFET portion and the deep layer;
a source region of the n-type disposed in a surface layer portion of the base region;
a trench gate structure including a gate insulating film disposed on a wall surface of a gate trench penetrating the source region and the base region, and a gate electrode disposed on the gate insulating film;
a source electrode electrically connected to the source region and the base region; and
a drain electrode electrically connected to the silicon carbide substrate, wherein
the deep layer, the JFET portion, and the low-concentration layer are disposed to form a built-in diode that allows a current to flow at a current density of 11.6 A/mm² or more during a freewheel operation of the built-in diode, and
the silicon carbide substrate contains boron at a concentration of 9.0×10¹⁶/cm³ or more in the silicon carbide substrate.

6. The silicon carbide semiconductor device according to claim 5, wherein
the current density during the freewheel operation of the built-in diode is 14.6 A/mm² or more, and
the concentration of the boron is 1.5×10¹⁷/cm³ or more.

7. The silicon carbide semiconductor device according to claim 5, wherein
the silicon carbide substrate has a thickness of 325 μm to 375 μm, and
the concentration of the boron is 1.75×10¹⁷/cm³ or less.

8. The silicon carbide semiconductor device according to claim 5, wherein
the silicon carbide substrate has a thickness of 475 μm to 525 μm, and
the concentration of the boron is 7.2×10¹⁷/cm³ or less.

9. The silicon carbide semiconductor device according to claim 5, wherein
the deep layer has a thickness of 1 μm or less.

10. The silicon carbide semiconductor device according to claim 5, further comprising:
a current distribution layer of the n-type disposed above the JFET portion and the deep layer and in contact with a distal end side in a depth direction of the gate trench; and
a linking layer of the p-type that links the base region and the deep layer, wherein
the base region is disposed above the current distribution layer and the linking layer, and
the deep layer is made of an ion-implantation layer and has a depth of 1 μm or more from a surface of the source region to a bottom of the deep layer.

11. The silicon carbide semiconductor device according to claim 5, wherein
the low-concentration layer is made of an epitaxial film disposed above the silicon carbide substrate.

12. A method for manufacturing an n-type silicon carbide single crystal, the method comprising:
placing a seed crystal on a surface of a pedestal disposed in a growth crucible;
manufacturing a silicon carbide ingot of the n-type silicon carbide single crystal by growing on a surface of the seed crystal by supplying a thermally decomposed silicon carbide raw material, an n-type dopant, and boron onto the surface of the seed crystal, so that a concentration of the boron in the silicon carbide ingot is 9.0×10¹⁶/cm³ or more and 1.75×10¹⁷/cm³ or less; and
slicing the silicon carbide ingot to form a 6-inch wafer or 8-inch wafer with a thickness of 325 μm to 375 μm.

13. The method according to claim 12, wherein
the manufacturing of the silicon carbide ingot includes:
placing a raw material powder below the pedestal, the raw material powder including a silicon carbide powder as the silicon carbide raw material and a boron raw material powder containing boron carbide or boron nitride as a raw material of the boron, and
thermally decomposing the raw material powder to be supplied to the seed crystal while supplying an n-type dopant, thereby to grow the silicon carbide ingot by a sublimation method.

14. The method according to claim 12, wherein
the manufacturing of the silicon carbide ingot includes:
supplying a silicon carbide raw material gas, an n-type dopant gas and a boron dopant gas from below the pedestal; and
thermally decomposing the silicon carbide raw material gas to be supplied to the seed crystal, thereby to grow the silicon carbide ingot by a gas growth method.

15. A method for manufacturing an n-type silicon carbide single crystal, the method comprising:
placing a seed crystal on a surface of a pedestal disposed in a growth crucible;
manufacturing a silicon carbide ingot of the n-type silicon carbide single crystal by growing on a surface of the seed crystal by supplying a thermally decomposed silicon carbide raw material, an n-type dopant, and boron onto the surface of the seed crystal, so that a concentration of the boron in the silicon carbide ingot is 9.0×10¹⁶/cm³ or more and 7.2×10¹⁷/cm³ or less; and
slicing the silicon carbide ingot to form an 8-inch wafer with a thickness of 475 μm to 525 μm.

16. The method according to claim 15, wherein
the manufacturing of the silicon carbide ingot includes:
placing a raw material powder below the pedestal, the raw material powder including a silicon carbide powder as the silicon carbide raw material and a boron raw material powder containing boron carbide or boron nitride as a raw material of the boron, and
thermally decomposing the raw material powder to be supplied to the seed crystal while supplying an n-type dopant, thereby to grow the silicon carbide ingot by a sublimation method.

17. The method according to claim 15, wherein
the manufacturing of the silicon carbide ingot includes:
supplying a silicon carbide raw material gas, an n-type dopant gas and a boron dopant gas from below the pedestal; and
thermally decomposing the silicon carbide raw material gas to be supplied to the seed crystal, thereby to grow the silicon carbide ingot by a gas growth method.
